(19) United States
(12) Patent Application Publication
(10) Pub. No.: US 2011/0030899 A1
(43) Pub. Date: Feb. 10, 2011

(54) PLASMA PROCESSING APPARATUS USING TRANSMISSION ELECTRODE

(76) Inventors: Keizo SUZUKI, Kodaira (JP); Masaru Izawa, Hino (JP); Nobuyuki Negishi, Tokyo (JP); Kenetsu Yokogawa, Tsurugashima (JP); Kenji Maeda, Kudamatsu (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/709,149

(22) Filed: Feb. 19, 2010

(30) Foreign Application Priority Data
Aug. 7, 2009 (JP) 2009-184776

(51) Int. Cl. C23F 1/08; C23C 16/00; C23C 16/50

(52) U.S. Cl. 156/345.43; 118/723 E

(57) ABSTRACT

At least a part of a discharging electromagnetic wave is introduced into a processing chamber via a transmission electrode which has characteristics to behave as a dielectric (electric insulator) for the discharging electromagnetic wave, and to behave as a material with electric conductivity for RF bias electromagnetic wave of electromagnetic wave of ion plasma oscillation.

### CLAIM OF PRIORITY

The present application claims priority from Japanese Patent Application JP 2009-184776 filed on Aug. 7, 2009, the content of which is hereby incorporated by reference into this application.

### FIELD OF THE INVENTION

The present invention relates to a plasma processing apparatus using a transmission electrode. More particularly, the present invention is effective for providing a plasma etching device or a plasma surface treatment device for processing a large-sized (large diameter) sample (hereinafter referred to as a wafer, a sample wafer, or a wafer sample) uniformly with high accuracy. In the specification, the plasma etching device or the plasma surface treatment device will be referred to as the plasma processing apparatus.

### BACKGROUND OF THE INVENTION

The plasma etching device has been employed to form a micro-pattern on a surface of the sample (normally a semiconductor wafer or a silicon wafer) for manufacturing the semiconductor element. The plasma etching device is used for transferring the preliminarily formed mask pattern on the sample surface as a concavo-convex pattern. Meanwhile, the plasma surface treatment device has been used for applying a certain chemical/physical processing on the sample surface for manufacturing the semiconductor element. The chemical/physical processing includes a shape processing such as the plasma etching, a film forming process such as CVD (Chemical Vapor Deposition), a reforming process such as surface oxidation and surface nitriding, and cleaning process such as aching and foreign body removal. The present invention will be described taking the plasma etching device mainly as related art. However, the present invention is widely applicable to the entire field of the plasma surface treatment device. As the present invention relates to the technology for the plasma formation which can be entirely applied to the plasma surface treatment device without being limited to the type of the surface treatment. As described above, the plasma etching device or the plasma surface treatment device will be referred to as the plasma processing apparatus hereinafter.

The plasma processing apparatus as typical related art will be described.

FIG. 24 illustrates an example of the plasma etching device as related art. Referring to the drawing, a plasma etching device 200 which uses magnetic microwave plasma includes a processing chamber 201 of which the inner space is evacuated. The etching gas (processing gas) is introduced into the processing chamber 201 and evacuated a part of the etching gas and a reaction gas produced through the etching reaction from the processing chamber 201. The gas at the pressure ranging from 10⁻² Pa to 100 Pa is normally introduced. However, such range does not have to be strictly observed. When the processing is required to be accelerated, or the gas is used for the film forming process, the pressure may be increased up to 1 kPa, or further to the atmospheric pressure (101 kPa). A discharging electromagnetic wave 202 is introduced into the processing chamber 201 via a discharging electromagnetic wave window 203. The discharging electromagnetic wave window 203 is normally formed of a dielectric (electric insulator) material such as quartz. The discharging electromagnetic wave 202 is supplied to the device shown in FIG. 24 through a circular waveguide 204. A magnetic field is formed by a cylindrical coil (solenoid coil) 205 inside the processing chamber 201.

Interaction among the magnetic field, the discharging electromagnetic wave 202, and the etching gas generates the discharge (plasma) at least in a part of the area inside the processing chamber 201, which is called magnetic microwave discharge (magnetic microwave plasma). The region where the discharge occurs will be referred to as a discharging region.

A sample mount table (a sample holding member) 206 is provided inside the processing chamber 201 such that the sample 207 is mounted on the sample mount table 206. The sample mount table 206 is electrically coupled with the sample 207. At least a part of the component of the sample mount table 206 is formed of the electric conductor. The sample mount table 206 is electrically coupled with a high frequency power source 208 via circuit. In the specification, “electric coupling via circuit” represents not only connection using the electric conductor but also the connection via the electric circuit component, for example, the capacitor, inductance, resistor and the switch. The function or device which makes the values of the capacitor, the inductance, and the resistance (impedance) variable may be provided. The “electric coupling via circuit” also represents physical connection (contact) between materials each with electric conductivity (that is, electric conductor or electric semi-conductor). For example, in the device shown in FIG. 24, the sample mount table 206 is connected to the high frequency power source 208 via a capacitor 209, to which high frequency voltage (RF voltage) is applied. Then bias voltage which contains direct current component (hereinafter referred to as direct current bias voltage, high frequency bias voltage or RF bias voltage) is automatically applied to the sample mount table 206 and the sample 207. At least a part of the wall surrounding the processing chamber is electrically coupled with a ground potential (earth potential) via circuit. The aforementioned wall is referred to as a ground potential wall. As a result, the high frequency current (RF current) is generated between the surface of the sample 207 and the ground potential wall. The RF bias voltage serves to direct the ion in the discharge (plasma) toward the sample surface at an accelerated rate to promote the physical/chemical surface reaction for etching. The ground potential wall may be in direct contact with the discharge via the metal surface (electric conductor), or indirect contact with the discharge by covering the metal surface with the dielectric (electric insulator) material with a predetermined thickness. The high frequency current (RF current) accompanied with the high frequency voltage (RF voltage) flows through the dielectric (electric insulator) material with the predetermined thickness so as to be transferred to the front surface of the metal of the ground potential wall. The thickness of the dielectric (electric insulator) material which covers the front surface of the metal is normally in the range from 1 mm to 10 mm. The discharge (that is, the sample surface) may be prevented from being contaminated by the metal material by covering the metal surface of the ground potential wall with the dielectric material.

During the discharge, electrons and ions are generated, and reactive radical is generated through dissociation of the etching gas. The reactive radical is an atomic element or a molecule which is electrically neutral with high chemical reactivity. Generally, the gas which contains Freon element such as CF₄, C₂F₆, C₃F₆, SF₆, Cl₂, and BCl₃, and the gas which contains the aforementioned types of the gas as constituents may be used as the etching gas. As a result, reactive radicals such as CF₃, CF₂, CF, F, Cl, BCl₂, and BCl are generated. The ion generated during the discharge is formed as the molecule of the etching gas or the reactive radical positively or negatively charged.

A mask pattern is preliminarily formed on the surface of the sample 207. The electron, ion and reactive radical which are generated during the discharge reach the surface of the sample 207 through the opening of the mask pattern. The aforementioned RF bias voltage allows incidence of the ion to the sample surface at the accelerated rate. As a result, the element which constitutes the sample, the incident ion or the element of the incident reactive radical reacts with one another on the surface. Such phenomenon is called the etching reaction. The etching reaction generates the evaporative (high vapor pressure) reaction product. The reaction product evaporates from the sample surface into the processing chamber as the product gas. The product gas will be evacuated from the processing chamber. In the aforementioned process, the mask pattern is transferred on the sample surface as the concavo-convex pattern on the sample surface. This is the plasma etching process.

The discharging electromagnetic wave 202 at the frequency f_{pf} in the range from 0.1 GHz to 10 GHz is normally employed. The frequency in the range from 0.5 GHz to 5 GHz is more generally employed, and the frequency of 2.45 GHz is especially employed. Generally, the higher the frequency f_{pf} becomes, the higher the density (electronic density) of the discharge (plasma) is formed. The cutoff frequency of the electromagnetic wave which propagates the plasma is proportional to the square root of the electronic density nₑ. This is because the discharging electromagnetic wave propagates into the plasma with high electronic density to form and maintain the plasma accompanied with increase in the frequency f_{pf} of the discharging electromagnetic wave. In view of this, the device shown in FIG. 24 generally uses the higher frequency f_{pf} (0.1 GHz to 10 GHz) compared with the device illustrated in FIG. 25 or other devices. If the frequency f_{pf} becomes too high, the cost of the discharging electromagnetic wave generation unit becomes high as well as the cost of the electron cyclotron resonance magnetic-field-forming unit to be described later. The upper limit of the frequency f_{pf} is defined by the aforementioned factors.

The magnetic flux density B₀ of the magnetic field formed by the cylindrical coil 205 inside the processing chamber 201, especially in the discharging region in the range from 0.01 T to 0.2 T is normally employed. There are at least two effects derived from formation of the magnetic field in the discharging region. Sealing of the plasma by the magnetic field is one effect, and efficient formation of the plasma using electron cyclotron resonance is the other effect. Any of the effects is useful to stably form the plasma at higher density (higher electronic density). That is, it is effective to efficiently introduce the discharging electromagnetic wave into the discharge region. The effect derived from sealing of the plasma becomes effective in the magnetic field at the magnetic flux density B₀ of approximately 0.01 T or higher. If the magnetic flux density B₀ becomes too high, the size of the facility and the running cost for the member (cylindrical coil 205 of the device illustrated in FIG. 24) for forming the magnetic field is increased. This may define the upper limit of the magnetic flux density B₀ of the magnetic field. Normally, the upper limit is approximately 0.2 T.

When the electron cyclotron resonance is used to form the plasma, the magnetic field at the flux density B₀ defined by the following formula (1) is at least partially formed inside the processing chamber 201.

B₀=2πf_{pf}mₑ/qₑ (1)

where
π: circle ratio, π≅3.14159,
f_{pf}: frequency of discharging electromagnetic wave [Hz]=[1/s],
mₑ: rest mass of electron [kg], mₑ≅9.109×10⁻³¹ kg,
qₑ: elementary charge [C], qₑ≅1.602×10⁻¹⁹ C

The formulae and physical quantity will be expressed in International System of Units, that is, SI (SI system of unit). The use of the electron cyclotron resonance allows formation of high density plasma (for example, nₑ (electronic density)=1×10¹⁷ m⁻³ to 1×10¹⁸ m⁻³) at the widely ranged gas pressure (for example, 0.01 Pa to 1000 Pa). Assuming that f_{pf}=5 GHz, the magnetic flux density (B₀) is equal to 0.179 T (B₀=0.179 T). Assuming that f_{pf}=2.45 GHz, B₀=0.0875 T is established. Assuming that f_{pf}=1 GHz, B₀=0.0357 T. Assuming that f_{pf}=0.5 GHz, B₀=0.0179 T.

The electromagnetic wave generated by the high frequency power source (RF bias electromagnetic wave) at the frequency f_{rb} in the range from 0.01 MHz to 100 MHz is generally used. The frequency f_{rb} in the range from 0.1 MHz to several tens MHz, and more generally, from 1 MHz to several tens MHz is employed. This is because ion acceleration with the RF bias is performed more efficiently and stably in the aforementioned frequency range.

Japanese Patent Application Laid-Open Publication No. H10-284299 discloses a plasma processing device which allows a discharging electromagnetic wave to be introduced into a processing chamber through a discharging electromagnetic wave window likewise the device illustrated in FIG. 24.

FIG. 25 illustrates another example of the generally employed plasma etching device. Referring to the drawing, an opposed electrode type plasma etching device 200 includes a processing chamber 201 which is evacuated. The etching gas is introduced into the processing chamber 201, and a part of the etching gas and the product gas generated from the etching reaction are evacuated. A discharging electromagnetic wave 202 is introduced into the processing chamber 201 through a discharging electromagnetic wave window 203. The discharging electromagnetic wave window 203 is generally formed of the dielectric (electric insulator) material such as quartz. In the device illustrated in FIG. 25, the discharging electromagnetic wave 202 is supplied from a coaxial waveguide 210. The coaxial waveguide 210 includes a center conductor 211 therein. The magnetic field is formed by the cylindrical coil 205 (solenoid coil) inside the processing chamber 201 in need. The aforementioned magnetic field is not necessarily required.

An opposed electrode 212 is provided while being electrically coupled with the center conductor 211 of the coaxial waveguide via circuit. The wall which surrounds the processing chamber 201, which is adjacent to the opposed electrode 212 (wall adjacent to the opposed electrode) is formed as the electric conductor normally at the ground potential. The discharging electromagnetic window 203 is provided in the gap (referred to the gap above opposed electrode) between the opposed electrode 212 and the wall adjacent above the opposed electrode). The discharging electromagnetic wave window 203 may be divided into (a) the region around the portion where the coaxial waveguide 210 is connected to the processing chamber 201, and (b) the region of the gap above the opposed electrode. The wall adjacent above the opposed electrode may be brought into direct contact with the discharge via the surface of the metal (electric conductor), or indirect contact with the discharge by covering the metal surface with the dielectric (electric insulator) material with the predetermined thickness. The reason is the same as the one described with respect to the related art example illustrated in FIG. 24.

A sample mount table (sample holding member) 206 is provided inside the processing chamber 201, on which a sample 207 is mounted. The sample mount table 206 is electrically coupled with the sample 207 via circuit. At least a part of the member for forming the sample mount table 206 is formed of the electric conductor.

The opposed electrode 212 and the sample mount table 206 are arranged to face with each other. The space defined by the opposed electrode 212 and the sample mount table 206 is referred to as an inter-electrode space. The discharging electromagnetic wave 202 supplied by the coaxial waveguide 210 propagates in the gap above the opposed electrode from inside (center conductor 211 of the coaxial waveguide) to outside (leading edge side of the opposed electrode 212) so as to be injected into the processing chamber 201 from the end of the discharging electromagnetic wave window 203. Then the injected discharging electromagnetic wave 202 propagates in the inter-electrode space from the outside to the inside.

Interaction between the discharging electromagnetic wave 202 and the etching gas propagating inside the processing chamber 201 generates the discharge (plasma) at least in a part of the inner region of the processing chamber. Especially the electromagnetic field in the inter-electrode space becomes sufficiently intensified to dominantly generate the discharge therein.

The sample mount table 206 is electrically coupled with the sample 207 via circuit. At least a part of the constituent of the sample mount table 206 is formed of the electric conductor. The sample mount table 206 is also electrically coupled with the high frequency power source 208 via circuit. For example, the sample mount table 206 is connected to the high frequency power source 208 via the capacitor 209 such that the high frequency voltage (RF voltage) is applied to the sample mount table 206. The bias voltage which contains the direct current component (hereinafter referred to as direct current bias voltage, high frequency bias voltage or RF bias voltage) is automatically applied to the sample mount table 206 and the sample 207. At least a part of the opposed electrode 212 is electrically coupled with the ground potential (earth potential) via circuit. As a result, RF current is generated between the surface of the sample 207 and the opposed electrode 212 via the discharge. The RF bias voltage allows incidence of the ion within the discharge (plasma) toward the sample surface at the accelerated rate. This makes it possible to promote physical/chemical surface reaction for etching.

The etching process using discharge (plasma), etching gas, RF bias voltage and RF current develops in similar conditions to those described with respect to the related art illustrated in FIG. 24.

The discharging electromagnetic wave 202 at the frequency f_{pf} ranging from 10 MHz to 1 GHz is normally used. The plasma with high density is likely to be formed as the frequency f_{pf} becomes higher. However, complicated standing wave is likely to be generated inside the inter-electrode space to deteriorate uniformity of the plasma. Practically, the actual discharging electromagnetic frequency f_{pf} is determined in consideration of the plasma density and uniformity.

The frequency f_{rb} of the electromagnetic wave (RF bias electromagnetic wave) generated in the high frequency power source is selected in the similar state to the one described with respect to the related art illustrated in FIG. 24.

The device illustrated in FIG. 25 has the device for introducing the etching gas connected to the opposite electrode 212 with piping. The etching gas flows through a gas inlet (or gas inlets) formed in the surface of the opposite electrode 212 at the side of the inter-electrode space so as to be supplied into the processing chamber 201.

As described above, the device illustrated in FIG. 25 has the opposed electrode 212 electrically coupled with the ground potential (earth potential) via circuit. The device with the same structure as described above may be designed to electrically couple the opposed electrode 212 with the high frequency power source via circuit. In such a case, the same power source may be used as the high frequency power source which electrically couples the sample mount table 206 via circuit (first high frequency power source) and a high frequency power source which electrically couples the opposed electrode 212 via circuit (second high frequency power source). Alternatively, they may be structured to be different.

Examples of the typical plasma etching device has been described as above.

### SUMMARY OF THE INVENTION

The problem to be addressed by the present invention becomes obvious especially when the diameter of the sample (wafer) subjected to the etching or surface treatment is increased. The “diameter of the sample” denotes the diameter of the sample which is assumed to have substantially a circular shape. Based on learning from experience, as the sample diameter becomes 200 mm or larger, the problem becomes obvious. In other words, as the diameter of the sample mount table becomes approximately 250 mm or larger, especially, 400 mm or larger, the problem becomes obvious.

Especially, the following problems are likely to occur as increase in the sample diameter for conducting the plasma etching and the surface treatment with further advanced characteristics.

The problems resulting from the increase in the sample diameter to be addressed by the present invention will be listed as follows:

(A) Fluctuation in the plasma potential with respect to time and space;
(B) Reduction in the plasma distribution uniformity;
(C) Difficulty in setting the required area of the RF current ground potential electrode; and
(D) Physical and chemical fluctuation in the surface state of the discharging side of the discharging electromagnetic window.

The aforementioned problems will be described in detail.

The problems which relate to the generally employed device with the structure illustrated in FIG. 24 ((A), (C) and (D)) will be described. In the related art device illustrated in FIG. 24, the discharging electromagnetic wave window 203 is formed of the dielectric (electric insulator) material, which causes the problems as described above.

In the plasma, the plasma potential is fluctuated with respect to time and space by ion plasma oscillation. At the normal plasma density (assuming that plasma density nₚ is equal to electron density nₑ, it is expressed as nₚ=nₑ=1×10¹⁶ m⁻³−1×10¹⁸ m⁻³), the frequency (oscillation frequency) fₚᵢ of the ion plasma oscillation is expressed as fₚᵢ=2 MHz to 20 MHz. In the device illustrated in FIG. 24, the discharging electromagnetic wave window 203 is formed of the dielectric (electric insulator) material, and no electric conducting material (electric semiconductor or electric conductor) for making the plasma potential uniform or stabilized exists around the discharging electromagnetic wave window 203. As a result, the problem of fluctuation in the plasma potential with respect to time and space occurs accompanied with the increase in the diameter of the discharging electromagnetic wave window 203 (problem (A1)).

When the high frequency voltage (RP voltage) is applied to the sample mount table 206 (that is, sample 207), the RF current is generated between the surface of the sample 207 and the ground potential wall (side wall of the processing chamber 201) via the discharge (plasma). The path length of the RF current becomes different between the center of the sample surface and the edge of the sample surface. This may also cause the fluctuation in the plasma potential with respect to time and space (problem (A2)).

As described above, when the high frequency voltage (RF voltage) is applied to the sample mount table 206 (sample 207, accordingly), the RF current is generated between the surface of the sample 207 and the ground potential wall via the discharge (plasma). At this time, if the area of the ground potential wall is sufficiently larger than that of the surface of the sample 207, most part of the RF bias voltage as the direct current component is applied between the sample surface and the plasma potential. This may efficiently accelerate the ion in the plasma toward the sample surface. Then the plasma potential with respect to the ground potential becomes substantially uniform. That is, the condition expressed by the following equation (2) is required for making the RF bias sufficiently effective.

Sₛₘ<<Sₑₜ (2)

where Sₛₘ: area of surface of the sample 207 [m²], area of the sample surface in contact with plasma,
Sₑₜ: area of ground potential wall [m²]

When the sample diameter increases, the formula (2) cannot be established. Assuming that the sample diameter is set to Dₛₘ, the Sₛₘ increases in proportional to the Dₛₘ², and Sₑₜ increases substantially in proportional to the Dₛₘ. That is, as the sample diameter increases, it is difficult to set the required area for the RF current ground potential electrode (problem (C)).

In the device illustrated in FIG. 24, the discharging electromagnetic wave window 203 is formed of the dielectric (electric insulator) material. As a result, the discharging surface of the discharging electromagnetic wave window (hereinafter window surface) is at the potential lower than the adjacent plasma potential by the amount corresponding to the floating voltage. Amount of positive/negative charge (normally, ion and electron) applied from the plasma to the window surface is equivalent. Sputtering or cleaning of the window surface using the ion accelerated at the floating voltage of normally 20V is less effective. In other words, the molecule produced through reaction of the sample etching is adhered to and deposited on a part of the window surface. As a result, the physical and chemical fluctuation in the surface state of the window is observed. The fluctuation is further enlarged as the diameter of the discharging electromagnetic wave window 203 increases owing to the reason described with respect to the problem (A) (Problem (D)).

The problem which relates to the generally employed device with the structure illustrated in FIG. 25 (problem (B)) will be described. As described above, in the device illustrated in FIG. 25, the discharging electromagnetic wave 202 propagates in the way as described below. That is, the discharging electromagnetic wave 202 supplied from the coaxial waveguide 210 propagates from the inner side (center conductor 211 of the coaxial waveguide) to the outer side (edge side of the opposed electrode 212) in the gap above the opposed electrode, and is injected from the end of the discharging electromagnetic window 203 into the processing chamber 201. The injected discharging electromagnetic wave 202 propagates from the outer side to the inner side in the inter-electrode space. The discharging electromagnetic wave 202 applies power to the plasma in the course of propagation from the outer side to the inner side in the inter-electrode space such that the intensity by itself is gradually reduced. The electromagnetic wave partially reflects on the center of the inter-electrode space to form the standing wave (stationary wave) therein. The resultant distribution of characteristics of the generated plasma (electron density, electron temperature) becomes no longer uniform. Such non-uniformity becomes obvious as the diameter of the sample mount table or the sample is increased (problem (B)).

Japanese Patent Application Laid-Open Publication NO. H10-284299 discloses the plasma device with a dielectric and a laminated window formed of the material which exhibits electric conductivity as the electromagnetic wave window for discharging. The laminated window includes an alumina window, an alumina protection film, and a laminated structure formed by laminating the titanium nitride thin film, conductive titanium thin film, and titanium nitride thin film between the window and the protection film. The laminated window may be formed to have a hemispherical shape, a conical shape, a cylindrical shape, or a flat disk shape, for example. An antenna connected to the high frequency power source at 13.56 MHz is wound around outside the laminated window.

Japanese Patent Application Laid-Open Publication No. H10-284299 does not disclose capability of uniformly processing the large-diameter sample by bringing the sample mount table and the laminated window into the opposed electrode arrangement in consideration of the aforementioned problems (A) to (D) resulting from the increase in the sample mount table or the sample diameter. The structure and conditions preferable to the aforementioned opposite electrode arrangement are never discussed. In Japanese Patent Application Laid-Open Publication No. H10-284299, the plasma processing apparatus using the magnetic field forming device is not discussed without recognizing stability and reliability of the cross impedance and the transmission electrode. The “cross impedance” will be described in detail in a first embodiment referring to FIG. 1.

In Japanese Patent Application Laid-Open Publication No. H10-284299, the plasma processing apparatus using the discharging electromagnetic wave at relatively high frequency f_{pf} ranging from 0.1 GHz to 10 GHz is not discussed. The task to form the high density plasma easily with high stability, high reliability and high function is not recognized.

The present invention provides a plasma etching device and a surface treatment device with advanced characteristics, that is, a plasma processing apparatus for addressing the problems (A) to (D) revealed from the increase in the sample diameter.

(A) fluctuation in plasma potential with respect to time and space;
(B) reduction of uniformity in the plasma distribution;
(C) difficulty in setting of required area for RF current ground potential electrode; and
(D) fluctuation in physical and chemical surface condition on the discharging surface of the discharging electromagnetic window.

According to the subject invention, a plasma processing apparatus for solving afore mentioned problems is realized by introducing the discharging electromagnetic wave into the processing chamber via the transmission electrode.

Typical features of the present invention will be listed as follows.

(1) A plasma processing apparatus includes a processing chamber, a unit for introducing processing gas into the processing chamber, a unit for partially generating a discharge in at least a part of a region in the processing chamber, and a sample holding unit for holding a sample, all of which form at least a part of a component for performing a plasma processing by introducing the sample into the processing chamber. The plasma processing apparatus further includes a unit for introducing a discharging electromagnetic wave into the processing chamber as at least a part of the unit for generating the discharge. At least a part of the discharging electromagnetic wave is introduced into a discharging region where the discharge is generated via a transmission electrode. A transmission electrode layer is provided as at least a part of a component of the transmission electrode. The transmission electrode layer is formed of an electric semiconductor or an electric conductor as a material with electric conductivity. The sample held by the sample holding unit and the transmission electrode or the transmission electrode layer are oppositely arranged.

(2) A plasma processing apparatus includes a processing chamber, a unit for introducing processing gas into the processing chamber, a unit for partially generating a discharge in at least a part of a region in the processing chamber, and a sample holding unit for holding a sample, all of which form at least a part of a component for performing a plasma processing by introducing the sample into the processing chamber. The plasma processing apparatus further includes a unit for introducing a discharging electromagnetic wave into the processing chamber as at least a part of the unit for generating the discharge. At least a part of the discharging electromagnetic wave is introduced into a discharging region where the discharge is generated via a transmission electrode. A transmission electrode layer is provided as at least a part of a component of the transmission electrode. The transmission electrode layer is formed of an electric semiconductor or an electric conductor as a material with electric conductivity. A unit for forming a magnetic field is provided in at least a part of the discharging region.

(3) A plasma processing apparatus includes a processing chamber, a unit for introducing processing gas into the processing chamber, a unit for partially generating a discharge in at least a part of a region in the processing chamber, and a sample holding unit for holding a sample, all of which form at least a part of a component for performing a plasma processing by introducing the sample into the processing chamber. The plasma processing apparatus further includes a unit for introducing a discharging electromagnetic wave into the processing chamber as at least a part of the unit for generating the discharge. At least a part of the discharging electromagnetic wave is introduced into a discharging region where the discharge is generated via a transmission electrode. A transmission electrode layer is provided as at least a part of a component of the transmission electrode. The transmission electrode layer is formed of an electric semiconductor or an electric conductor as a material with electric conductivity. A frequency of the discharging electromagnetic wave is in a range from 0.1 GHz to 10 GHz.

(4) A plasma processing apparatus includes a processing chamber, a unit for introducing processing gas into the processing chamber, a unit for partially generating a discharge in at least a part of a region in the processing chamber, and a sample holding unit for holding a sample, all of which form at least a part of a component for performing a plasma processing by introducing the sample into the processing chamber. The plasma processing apparatus further includes a unit for introducing a discharging electromagnetic wave into the processing chamber as at least a part of the unit for generating the discharge. At least a part of the discharging electromagnetic wave is introduced into a discharging region where the discharge is generated via a transmission electrode. A transmission electrode layer is provided as at least a part of a component of the transmission electrode. The transmission electrode layer is formed of an electric semiconductor or an electric conductor as a material with electric conductivity. A resistivity of a material for forming the transmission electrode layer is equal to or smaller than 3×10⁻⁷ Ωm.

(5) A plasma processing apparatus includes a processing chamber, a unit for introducing processing gas into the processing chamber, a unit for partially generating a discharge in at least a part of a region in the processing chamber, and a sample holding unit for holding a sample, all of which form at least a part of a component for performing a plasma processing by introducing the sample into the processing chamber. The plasma processing apparatus further includes a unit for introducing a discharging electromagnetic wave into the processing chamber as at least a part of the unit for generating the discharge. At least a part of the discharging electromagnetic wave is introduced into a discharging region where the discharge is generated via a transmission electrode. A transmission electrode layer is provided as at least a part of a component of the transmission electrode. The transmission electrode layer is formed of an electric semiconductor or an electric conductor as a material with electric conductivity. When physical quantity is expressed in International System of Units (SI system of units), following formulae (A1) to (A3) are established.

ρₜₑ_{_{—}}_{RW}(R_{W}_{_{—}}ₜₑ=0.97)<ρₜₑ<ρₜₑ_{_{—}}_{Vrb}(ΔV_{rb}_{_{—}}ₜₑ=3V) (A1)

ρₜₑ_{_{—}}_{RW}=((2dₜₑ/ln(R_{W}_{_{—}}ₜₑ))²μₜₑ ω̅_{pf})/2 (A2)

ρₜₑ_{_{—}}_{Vrb}=(4dₜₑΔV_{rb}_{_{—}}ₜₑ)/(iᵢₛrₜₑ²) (A3)

where:
ρₜₑ: resistivity of transmission electrode layer,
dₜₑ: thickness of transmission electrode layer,
R_{W}_{_{—}}ₜₑ: power transmission factor of discharging electromagnetic wave in transmission electrode layer,
μₜₑ: permeability of transmission electrode layer,
ω_{pf}: angular frequency of discharging electromagnetic wave,
ΔV_{rb}_{_{—}}ₜₑ: RF drop voltage in transmission electrode layer,
iᵢₛ: incident ion current density of transmission electrode to the surface at discharging region side, and rₜₑ: radius or equivalent radius of transmission electrode layer.
The formula (B1) provides the value of ρₜₑ_{_{—}}_{RW} by calculating the formula (A2) using R_{W}_{_{—}}ₜₑ=0.97, and the formula (B2) provides the value of ρₜₑ_{_{—}}_{Vrb} by calculating the formula (A3) using ΔV_{rb}_{_{—}}ₜₑ=3V.

ρₜₑ_{_{—}}_{RW}(R_{W}_{_{—}}ₜₑ=0.97) (B1)

ρₜₑ_{_{—}}_{Vrb}(ΔV_{rb}_{_{—}}ₜₑ=3V) (B2)

(6) In any one of the above plasma processing apparatus (1)˜(5), a bus electrode is provided as a part of the component of the transmission electrode. The bus electrode is formed of the electric semiconductor or the electric conductor as a material with electric conductivity. At least a part of the bus electrode is electrically coupled with at least a part of the transmission electrode layer via circuit.

(7) In the plasma processing apparatus (6), the transmission electrode layer is divided into plural regions by the bus electrode.

(8) In any one of the above plasma processing apparatus (1)˜(5), at least a transmission electrode layer missing region is formed in at least a part of the transmission electrode layer. The transmission electrode layer missing region is configured in the transmission electrode layer where the material with electric conductivity for forming the transmission electrode layer is missing.

(9) In the plasma processing apparatus (8), at least a part of the processing gas is introduced into the processing chamber through the transmission electrode layer missing region formed in the transmission electrode layer.

(10) In any one of the above plasma processing apparatus (1)˜(5), a thickness of the transmission electrode layer changes depending on a radial or circumferential position of the processing chamber.

According to the present invention, at least a portion of the discharging electromagnetic wave may be introduced into the processing chamber via the transmission electrode to suppress fluctuation in the plasma distribution, plasma potential, etching characteristic, or surface treatment characteristic with respect to time and space, thus realizing the plasma processing apparatus with high controllability and reliability. The plasma processing apparatus is allowed to process the large-diameter sample with high uniformity.

### BRIEF DESCRIPTION OF THE DRAWINGS

Exemplary embodiments of the present invention will be described in detail based on the following figures, wherein:

FIG. 1 is a vertical sectional view of a plasma processing apparatus according to a first embodiment of the present invention;

FIG. 2A illustrates a basic structure of a transmission electrode according to the present invention, and a state of its use;

FIG. 2B illustrates the basic structure of the transmission electrode according to the present invention, and a state of another use;

FIG. 3 illustrates a drop voltage in the transmission electrode by RF current and an induced voltage in the electrode protection layer according to the present invention;

FIG. 4 is a graph showing a region of R_{W}_{_{—}}ₜₑ>0.80 and ΔV_{rb}_{_{—}}ₜₑ<50V on the coordinate system of thickness dₜₑ and resistivity ρₜₑ of the transmission electrode layer according to the present invention;

FIG. 5 is a graph showing a region of R_{W}_{_{—}}ₜₑ>0.50 and ΔV_{rb}_{_{—}}ₜₑ<5V on the coordinate system of thickness dₜₑ and resistivity ρₜₑ of the transmission electrode layer according to the present invention;

FIG. 6 is a graph showing a region of R_{W}_{_{—}}ₜₑ>0.90 and ΔV_{rb}_{_{—}}ₜₑ<25V on the coordinate system of thickness dₜₑ and resistivity ρₜₑ of the transmission electrode layer according to the present invention;

FIG. 7 is a graph showing a region of R_{W}_{_{—}}ₜₑ>0.95 and ΔV_{rb}_{_{—}}ₜₑ<10V on the coordinate system of thickness dₜₑ and resistivity ρₜₑ of the transmission electrode layer according to the present invention;

FIG. 8 is a graph showing a region of R_{W}_{_{—}}ₜₑ>0.97 and ΔV_{rb}_{_{—}}ₜₑ<3V on the coordinate system of thickness dₜₑ and resistivity ρₜₑ of the transmission electrode layer according to the present invention;

FIG. 9 is a graph showing a region of R_{W}_{_{—}}ₜₑ>0.98 and ΔV_{rb}_{_{—}}ₜₑ<2V on the coordinate system of thickness dₜₑ and resistivity ρₜₑ of the transmission electrode layer according to the present invention;

FIG. 10 is a graph showing a contour on the coordinate system of thickness dₜₑ and resistivity ρₜₑ of the transmission electrode layer according to the present invention while holding value of R_{W}_{_{—}}ₜₑ constant;

FIG. 11 is a graph showing a contour on the coordinate system of thickness dₜₑ and resistivity ρₜₑ of the transmission electrode layer according to the present invention while holding ΔV_{rb}_{_{—}}ₜₑ constant;

FIG. 12A is a graph showing dependency of the power transmission factor R_{W}_{_{—}}ₜₑ and RF drop voltage ΔV_{rb}_{_{—}}ₜₑ on the thickness dₜₑ of the transmission electrode layer according to the present invention (Al (resistivity ρₜₑ=2.7×10⁻⁸ Ωm) is assumed as the material for forming the transmission electrode layer);

FIG. 12B is a partially enlarged view of FIG. 12A;

FIG. 13A is a graph showing dependency of the power transmission factor R_{W}_{_{—}}ₜₑ and RF drop voltage ΔV_{rb}_{_{—}}ₜₑ on the thickness dₜₑ of the transmission electrode layer according to the present invention (Cr (resistivity ρₜₑ=1.9×10⁻⁷ Ωm) is assumed as the material for forming the transmission electrode layer);

FIG. 13B is a partially enlarged view of FIG. 13A;

FIG. 14A is a graph showing dependency of the power transmission factor R_{W}_{_{—}}ₜₑ and resistivity ρₜₑ on the thickness dₜₑ of the transmission electrode layer at the RF drop voltage ΔV_{rb-te}=10V according to the present invention;

FIG. 14B is a partially enlarged view of FIG. 14A;

FIG. 15A is a graph showing dependency of the power transmission factor R_{W}_{_{—}}ₜₑ and resistivity ρₜₑ on the thickness dₜₑ of the transmission electrode layer at the RF drop voltage ΔV_{rb}_{_{—}}ₜₑ=100V according to the present invention;

FIG. 15B is a partially enlarged view of FIG. 15A;

FIG. 16 is a vertical sectional view of a plasma processing apparatus according to a second embodiment of the present invention;

FIG. 17 is a sectional view of a transmission electrode and a peripheral region according to a third embodiment of the present invention;

FIG. 18 is a sectional view of a transmission electrode according to a fourth embodiment of the present invention;

FIG. 19 is a sectional view of a transmission electrode and a peripheral region according to a fifth embodiment of the present invention;

FIG. 20A is a sectional view of a transmission electrode and a peripheral region according to a sixth embodiment of the present invention;

FIG. 20B is a view schematically showing a unit for cooling the transmission electrode with a transmission electrode cooling function using the cooling gas flow in the sixth embodiment;

FIG. 21 is a sectional view of a transmission electrode according to a seventh embodiment of the present invention;

FIG. 22 is a sectional view of a transmission electrode according to an eighth embodiment of the present invention;

FIG. 23A is a plan view showing an example of a bus electrode according to the eighth embodiment of the present invention;

FIG. 23B is a plan view showing another example of the bus electrode according to the eighth embodiment of the present invention;

FIG. 24 is a sectional view illustrating a related art magnetic field microwave plasma etching device; and

FIG. 25 is a sectional view illustrating a related art opposed electrode type plasma etching device.

### DESCRIPTION OF THE PREFERRED EMBODIMENTS

Embodiments of the present invention will be described referring to the drawings. In all the drawings representing embodiments, the element with the same function as that of the related art will be designated with the same code, and explanation thereof, thus will be omitted.

### First Embodiment

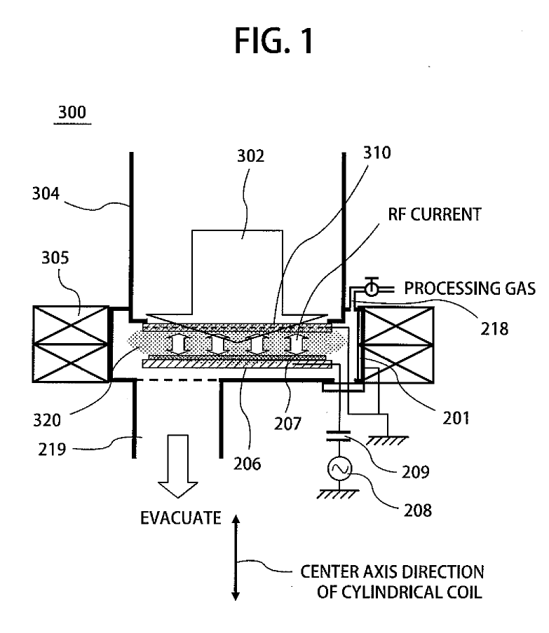

A plasma processing apparatus according to a first embodiment of the present invention will be described referring to FIGS. 1 to 16. FIG. 1 is a vertical sectional view of a plasma processing apparatus 300 according to the first embodiment of the present invention. A discharging electromagnetic wave 302 is supplied from a circular waveguide 304. A transmission electrode (transmission electrode layer) 310 is provided between the circular waveguide 304 and a processing chamber 201. The transmission electrode 310 is provided opposite a sample mount surface of a sample mount table 206 inside the processing chamber 201, thus forming an opposed electrode structure having the transmission electrode 310 and the sample 207 oppositely arranged. A cylindrical coil (solenoid coil) 305 as a member for forming the magnetic field is provided around the processing chamber 201. Frequency f_{pf} of the discharging electromagnetic wave 302 is ranged from 0.1 GHz to 10 GHz. Etching gas (processing gas) is introduced into the processing chamber 201 via a processing gas inlet 218. A part of the etching gas in the processing chamber 201 and the product gas generated through the etching reaction are evacuated outside through an outlet 219.

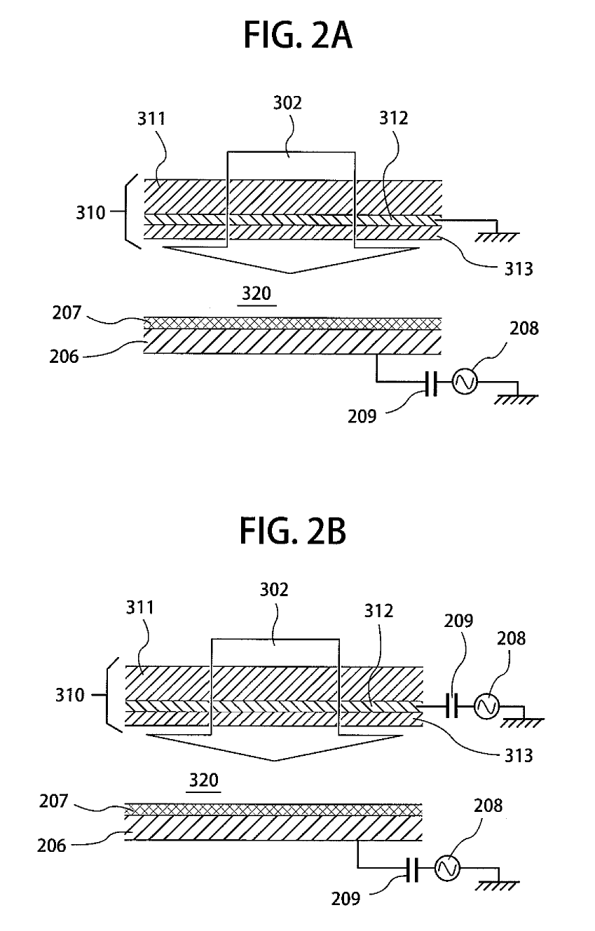

FIG. 2A illustrates an example of a structure of the transmission electrode 310. The transmission electrode 310 has a flat structure formed by laminating a transmission electrode layer 312 and an electrode protection layer 313 on a surface of an electrode substrate 311. The transmission electrode layer 312 is formed of an electric semiconductor or an electric conductor as the material with electric conductivity. In this example, the transmission electrode layer 312 of the transmission electrode 310 is electrically coupled with the ground potential via circuit. The sample mount table 206 is connected to the high frequency power source 208 via a capacitor 209, to which high frequency voltage (RF voltage) is applied.

In the present embodiment, the discharging electromagnetic wave 302 (or a part of the discharging electromagnetic wave 302) is introduced into a discharging region 320 in the processing chamber 201 through the transmission electrode 310. As the transmission electrode layer 312 is electrically coupled with the ground potential via circuit, the RF current may be applied to the ground potential.

The transmission electrode layer 312 may be brought to a floating potential as the equivalent structure of the embodiment (not shown in FIG. 1). The transmission electrode layer 312 may be electrically coupled with the high frequency power source 208 via circuit as described later.

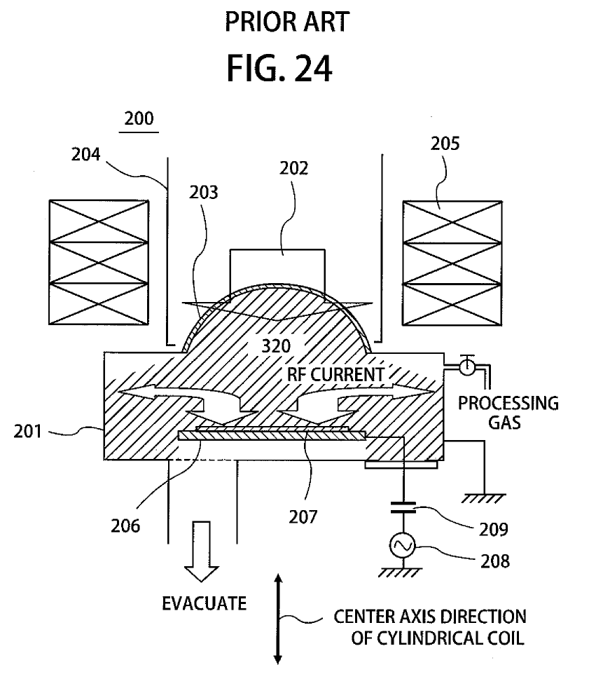

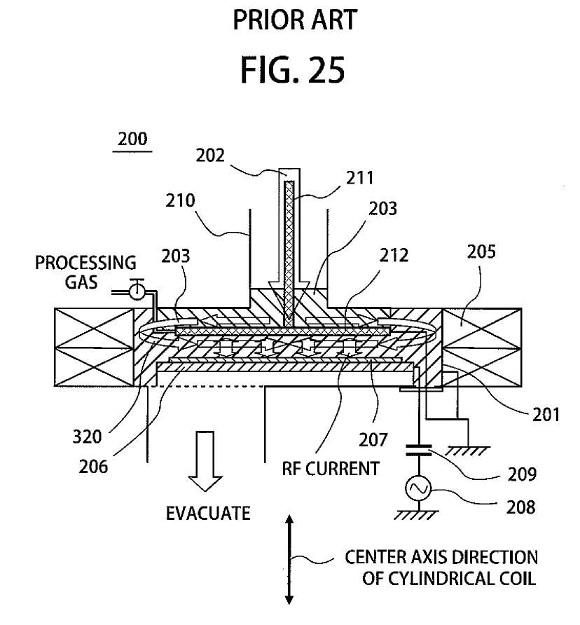

Both the frequency f_{pf} of the discharging electromagnetic wave 302 and the frequency f_{rb} of the RF bias electromagnetic layer in the apparatus according to the embodiment are equivalent to the one explained with respect to the related art device shown in FIGS. 24 and 25. The detailed description with respect to the property applicable to the plasma processing apparatus according to the present invention, for example, the structure of the sample mount table inside the processing chamber 201, the etching gas, and physical/chemical surface reaction for the etching, the discharging magnetic field and the like will be omitted.

In this embodiment, the transmission electrode 310 is structured to behave as the dielectric (electric insulator) for the discharging electromagnetic wave (normally, the frequency f_{pf}=0.01 GHz to 10 GHz), and it is formed of the material and structure with electric conductivity for the RF bias electromagnetic wave (normally, f_{rb}<f_{pf} when f_{rb}=0.01 MHz to 100 MHz), or the electromagnetic wave of the ion plasma oscillation (frequency fₚᵢ=2 MHz to 20 MHz). Specially, when it is preferable to form the discharge (plasma) at high density (high electron density) in the embodiment, the frequency f_{pf} of the discharging electromagnetic wave 302 is required to be set in the range from 0.1 GHz to 10 GHz. In the device according to the present embodiment, the transmission electrode 310 serves as a vacuum wall which bears the differential pressure between the atmospheric pressure and the inner pressure of the processing chamber. However, the transmission electrode 310 does not have to serve as the vacuum wall. The transmission electrode 310 may be provided inside the processing chamber.

Referring to FIG. 1, unlike the related art device as illustrated in FIG. 24, in the present embodiment having the opposed electrode structure where the transmission electrode 310 is arranged opposite the sample 207, the RF current flows between the sample and the transmission electrode 310 in substantially perpendicular direction with respect to the treatment surface of the sample 207 for entire region, while having the current path length being kept constant irrespective of the position on the sample surface. In other words, distribution of the ion acceleration (kinetic energy of ion) incident to the sample surface is uniform over the surface to be processed of the sample 207. In the embodiment, most of the required area for the RF current ground potential electrode is occupied by the transmission electrode 310. Unlike the related art device as illustrated in FIG. 24, the area of the RF current ground potential electrode to be defined on the side wall of the processing chamber 201 may be reduced, thus further reducing the capacity (diameter and height) of the processing chamber. This makes it possible to provide the cylindrical coil (solenoid coil) 305 as the element for forming the magnetic field around the processing chamber 201 without enlarging the plasma processing apparatus as a whole and without increasing the cost of the element for forming the magnetic field. Accordingly, the magnetic field distribution may be made further uniform around the sample.

Unlike the related art device for supplying the discharging electromagnetic wave to the portion around the center on the surface to be processed of the sample by the coaxial waveguide as illustrated in FIG. 25, the present embodiment suppresses generation of the complicated standing wave in the inter-electrode space. This makes it possible to make distribution of the electromagnetic wave intensity uniform in the plane of the surface to be processed of the sample 207.

The plasma processing apparatus according to the present invention is capable of generating uniform plasma over a whole region in the plane of the surface to be processed of the sample 207, which allows the large-diameter sample to be uniformly processed.

The structure of the transmission electrode 310 according to the present embodiment will be briefly described. The transmission electrode 310 has a structure provided with the transmission electrode layer 312 and the electrode protection layer 313 on the surface of the electrode substrate 311, for example. Those layers may be provided through lamination, or physical/chemical attachment. The electrode substrate 311 is formed of such dielectric as quartz, which has a thickness of 10 mm. The electrode substrate 311 is designed to have the thickness sufficient to bear the differential pressure between the atmospheric pressure and the inner pressure of the processing chamber. The transmission electrode layer 312 is formed of Al with thickness of 50 nm. The electrode protection layer 313 is formed of the dielectric such as quartz with thickness of 1 mm. The specific structure and the constituent material of the transmission electrode 310 will be described in more detail later.

Addressing the problems (A) (or (A1, (A2)), (B), (C), and (D) of the related art device using the apparatus according to the present embodiment will be described in the section “Basic structure of transmission electrode”.

The plasma processing apparatus of opposed electrode type, and the plasma processing apparatus with the unit for forming the magnetic field in the processing chamber or the discharging region may further provide special effects. The special effects will be described referring to the apparatus according to the embodiment shown in FIG. 1 and the related art device shown in FIG. 24.

In the apparatus of the present embodiment and the related art device, the magnetic field is generated inside the processing chamber 201 by the cylindrical coils (solenoid coils) 205, 305. Generally, the cylindrical coil (solenoid coil) may be defined as the “magnetic field forming member 205 or 305”, which does not have to have a cylindrical or coil shape. For example, the permanent magnet may be used to generate the magnetic field inside the processing chamber 201.

Generation of the magnetic field inside the processing chamber, especially in the discharging region will be discussed. Generally, the plasma (discharge) may be easily moved or diffused in the magnetic field direction (direction of magnetic field vector). Conversely, it is difficult for the plasma (discharge) to move or diffuse in the direction which intersects (especially orthogonal direction) the magnetic field direction (magnetic field vector direction). In consideration of the aforementioned point, the sample 207 is disposed in the related art device illustrated in FIG. 24 and the apparatus according to the embodiment illustrated in FIG. 1 so as to have the surface positioned orthogonal to the magnetic field vector direction. In other words, the sample 207 is disposed such that the normal vector of the surface is in substantially parallel with the magnetic field vector. Specifically, it is disposed such that the center axis direction of the cylindrical coil 305 (direction substantially in accord with the magnetic field vector to be formed, up/down direction illustrated in FIG. 24 and 1 shown in the drawing) is in parallel with the direction of the normal vector of the surface of the sample 207. This efficiently allows incidence of the generated plasma to the sample surface.

The related art device illustrated in FIG. 24 will be described in consideration of the arrangement as described above. Application of the RF bias allows the RF current to flow between the sample 207 and the side wall of the processing chamber (ground potential power source). At this moment, in the related art device illustrated in FIG. 24, the RF current path partially passes the magnetic field (magnetic field vector) substantially orthogonally as the line connected between at least a part of the region on the sample surface and the side wall of the processing chamber 201 intersects the direction of the magnetic field vector (direction of the center axis of the cylindrical coil 205). Generally in the plasma to which the magnetic field is applied, impedance (cross impedance) in the direction across the magnetic field (magnetic field vector) orthogonally (generally, intersecting direction) is enlarged compared with the impedance in the direction substantially in parallel with the magnetic field (magnetic field vector). That is, when the RF current flows in the direction orthogonal to the magnetic field (magnetic field vector), a large voltage drop (potential change) occurs. Such phenomenon is called cross impedance, and the voltage drop (potential change) caused by the cross impedance. In the related art device illustrated in FIG. 24, the voltage drop (potential change) owing to the cross impedance causes large fluctuation (dependency on the surface position) dependent on the position by the acceleration energy (kinetic energy) of the ion incident to the sample surface. This is because the resistance value (impedance) of the current path defined by the center region of the sample and the side wall of the processing chamber is largely different from the resistance value (impedance) of the current path defined by the end region (outer peripheral region) of the sample and the side wall of the processing chamber. As a result, surface fluctuation occurs in the etching characteristics or the surface treatment characteristics. Especially in the center region of the sample, the voltage drop (potential change) owing to the cross impedance is large, and accordingly, the acceleration energy of the incident ion is largely reduced. That is, in the center region of the sample, the effect of the RF bias application is diminished. The voltage drop (potential change) owing to the cross impedance fluctuates the plasma potential in contact with the sample surface depending on the sample surface position. As a result, potential difference occurs in the sample (for example, between the center region and the edge region of the sample), leading to destruction of the electronic device formed on the sample surface. Such surface fluctuation and characteristic change caused in the etching device or the surface treatment device may deteriorate process performance and reliability of the device. The aforementioned problems may be obvious as the sample diameter is increased.

The apparatus according to the first embodiment of the present invention will be described. The apparatus is different from the related art device illustrated in FIG. 24 in that the transmission electrode 310 is provided opposite the sample 207, that is, the sample mount surface of the sample mount table 206. Such arrangement of the electrode will be referred to as opposed electrode arrangement. As described above, the transmission electrode layer 312 of the transmission electrode 310 is electrically coupled with the ground potential via circuit. The transmission electrode 310 serves as the ground potential electrode for the RF current. The characteristic of the transmission electrode according to the present invention realizes the aforementioned arrangement and function as described above. In the apparatus with the aforementioned arrangement and function, the RF current flows between the sample 207 and the transmission electrode 310 as shown in FIG. 1. The current is applied such that the path resistance value (path impedance) is reduced, that is, the path length is substantially reduced. The RF current flows with substantially constant path length in parallel with the magnetic field vector direction (direction of the center axis of the cylindrical coil 305) irrespective of the sample surface position. Accordingly, the resistance value (path impedance) of the RF current becomes substantially constant irrespective of the sample surface position as FIG. 1 clearly shows. No cross impedance occurs, thus reducing the path resistance value (path impedance) of the RF current. This may make the acceleration energy (kinetic energy) of the incident ion to the sample surface constant without fluctuation depending on the position. The voltage drop on the RF current path is also reduced. The loss of the acceleration energy of the incident ion is small to allow the RF bias application to act more efficiently. The destruction of the electronic device in the sample surface caused by the voltage drop owing to the cross impedance does not occur. As a result, the process performance and reliability of the apparatus according to the present embodiment are largely improved. The RF bias application to the opposed electrode arrangement of the apparatus according to the present invention will be referred to as opposed electrode type RF bias application method (or opposed electrode type RF bias method).

The “opposed electrode arrangement” may be defined as “arrangement where the sample 207 is normally arranged opposite the transmission electrode 310 (transmission electrode layer 312)”. It may be quantitatively defined by the following formulae (3) to (6).

h_{d}<adₛ (3)

a≦1 (4)

Δh_{d}<bh_{d} (5)

b≦1/2 (6)

where
dₛ: diameter [m] of the sample, or equivalent diameter of the sample;
h_{d}: average value [m] of height of the discharge region, average value of the distance between the sample surface and the surface of oppositely arranged transmission electrode (or transmission electrode layer surface) on the sample surface;
a: allowable aspect ratio;
Δh_{d}: value [m] of variable with respect to height of the discharge region, value of variable with respect to the distance between the sample surface and the oppositely arranged transmission electrode surface (transmission electrode layer surface) on the sample surface, difference between maximum value and minimum value of the distance on the sample surface (maximum value-minimum value);
b: allowable variable ratio.

The equivalent diameter of the sample is set as the diameter of the circle with the same area as that of the sample which does not have a circular shape. The conditions in the formulae (3) and (4) are set for the purpose of allowing most of the RF current to flow between the sample 207 and the transmission electrode 310 while preventing the flow between the sample 207 and the side wall of the processing chamber 201. Generally, a=1 is set. However, if the RF current flowing to the side wall of the processing chamber 201 is required to be strictly limited, a=0.5, or a=0.1 has to be set. The conditions in the formulae (5) and (6) are set such that the RF current flows with substantially constant path length irrespective of the sample surface position, that is, the path resistance value (path impedance) of the RF current becomes constant irrespective of the sample surface position. Generally, b=1/2 is set. However, if the path resistance value of the RF current is required to be made constant more strictly, b=0.1 or b=0.05 has to be set.

As described above, the present invention provides the effects for “largely improving process performance and reliability of the plasma processing apparatus with magnetic field forming member by addressing the problem of cross impedance or voltage drop (potential change) owing to cross impedance”, and further for “making the path resistance value of RF current constant to improve process performance and reliability of the plasma processing apparatus by oppositely arranging the sample and transmission electrode (or transmission electrode layer)”.

The effect for “largely improving process performance and reliability of the plasma processing apparatus with magnetic field forming member by addressing the problem of cross impedance or voltage drop (potential change) owing to cross impedance” is not limited to the apparatus of the embodiment illustrated in FIG. 1. It is obvious that such effect is generally available for the plasma processing apparatus with the magnetic field forming member. The effect for “making the path resistance value of RF current constant to improve process performance and reliability of the plasma processing apparatus by oppositely arranging the sample and transmission electrode (or transmission electrode layer) is not limited to the apparatus of the embodiment illustrated in FIG. 1. It is obvious that such effect is generally available for the plasma processing apparatus having the sample and the transmission electrode (or transmission electrode layer) oppositely arranged.

In the first embodiment of the present invention, “the high frequency antenna (antenna)” is not employed as the member for introducing the discharging electromagnetic wave to the discharging region. The frequency f_{pf} of the discharging electromagnetic wave is relatively large in the range from 0.1 GHz to 10 GHz. The apparatus illustrated in FIG. 1 forms the magnetic field in the discharging region instead of using the high frequency antenna to allow efficient introduction of the discharging electromagnetic wave to the discharging region.

The apparatus according to the first embodiment of the present invention employs the discharging electromagnetic wave at relatively high frequency f_{pf} in the range from 0.1 GHz to 10 GHz. As described with respect to the related art, the plasma at high density (high electron density nₑ) may be easily formed. This feature is essentially different from the one disclosed in Japanese Patent Application Laid-Open Publication No. H10-284299 which employs the high frequency antenna as the essential member for introducing the discharging electromagnetic wave to the discharging region, and the frequency f_{pf} for the discharging electromagnetic wave is set to the value around 13.56 MHz. When the high frequency antenna is employed as described in Japanese Patent Application Laid-Open Publication No. H10-284299, the magnetic field is intensively generated around the antenna electrode. The transmission electrode layer or the electrode protection layer around the region are likely to be destroyed because of local heat generation, abnormal discharge or local intensified discharge caused by the intensive magnetic field. The first embodiment which does not employ the high frequency antenna has no such problems.

The frequency f_{pf} of the discharging electromagnetic wave is increased, and the transmission electrode is employed to form the high density plasma easily and highly reliably with high function. The present invention provides effects for “improving stability and reliability of the transmission electrode by introducing the discharging electromagnetic wave to the discharging region highly efficiently using the magnetic field instead of the high frequency antenna” and for “forming the high density plasma easily and highly reliably with high function using the discharging electromagnetic wave at the frequency f_{pf} with relatively large value in the range from 0.1 GHz to 10 GHz and the transmission electrode according to the present invention”. The apparatus according to the first embodiment of the present invention has been made by recognizing the aforementioned effects.

The effect for “largely improving stability and reliability of the transmission electrode of the present invention by highly efficiently introducing the discharging electromagnetic wave to the discharging region using the magnetic field instead of the high frequency antenna” is not limited to the apparatus of the first embodiment. Such effect may be generally derived from the plasma processing apparatus using the member for forming the magnetic field instead of the high frequency antenna. The effect for “forming the high density plasma with ease, high stability, high reliability and high function by using the discharging electromagnetic wave at the relatively high frequency f_{pf} in the range from 0.1 GHz to 10 GHz and the transmission electrode according to the present invention” is not limited to the apparatus of the first embodiment. Such effect may be derived from the plasma processing apparatus using the discharging electromagnetic wave at relatively high frequency f_{pf} in the range from 0.1 GHz to 10 GHz.

Characteristics of the first embodiment and the effect derived from the present invention as described above become further obvious when the sample diameter is increased to be equal to or larger than 250 mm, and further equal to or larger than 400 mm.

The following description relates to the preferred structure of the transmission electrode in the plasma processing apparatus having the sample and the transmission electrode oppositely arranged for performing the process with high uniformity when the diameter of the sample is increased to approximately 250 mm or larger, or further 400 mm or larger, and discussion with respect to the structure.

### [Basic Structure of Transmission Electrode]

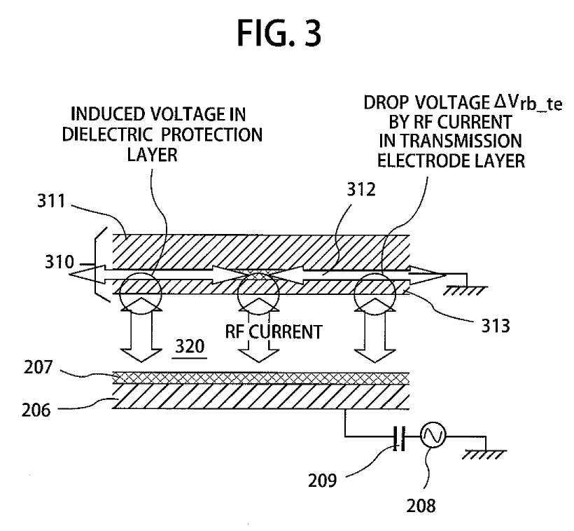

The basic structure of the transmission electrode according to the present invention will be described referring to FIGS. 2A to 3.

The aforementioned problems (A) to (D) to be addressed by the present invention are caused by such factors:

(1) The discharging electromagnetic wave window 203 is formed of a dielectric (electric insulator) material (related art device with the structure illustrated in FIG. 24); or
(2) The discharging electromagnetic wave 202 propagates in the inter-electrode space from the outer side to the inner side (related art device with the structure illustrated in FIG. 25).

The method for introducing at least a part of the discharging forming electromagnetic wave to the discharging region via the transmission electrode is the most fundamental way for addressing those problems. The transmission electrode has characteristics to behave as the dielectric (electric insulator) for the discharging electromagnetic wave (frequency f_{pf} is normally in the range from 0.01 GHz to 10 GHz), and to behave as a material with electric conductivity (electric semiconductor or electric conductor) for the electromagnetic wave of the ion plasma oscillation (frequency fₚᵢ is substantially in the range from 2 MHz to 20 MHz. The behavior of the “transmission electrode as the dielectric for the discharging electromagnetic wave” represents that “most part of the discharging electromagnetic wave incident to the transmission electrode transmits the transmission electrode”. The behavior of the “transmission electrode to provide electric conductivity for the electromagnetic wave with ion plasma oscillation” represents that “the transmission electrode allows the current flow of the RF bias electromagnetic wave or the ion plasma oscillation electromagnetic wave without causing the voltage drop (under the condition where the voltage at the voltage drop is sufficiently lower than the amplitude voltage of the electromagnetic wave or the peak-to-peak voltage)”. Availability of the aforementioned characteristics for the transmission electrode will be described later. If those characteristics are available for the transmission electrode, the aforementioned causes (1) and (2) may be resolved, and accordingly, it is clear to overcome the problems (A) to (D). The solution of the problems (A) to (D) by the transmission electrode will be supplementarily described referring to FIGS. 2A and 2B.

FIGS. 2A and 2B illustrate the basic structure of the transmission electrode and its use, respectively. The transmission electrode 310 is formed, by providing the transmission electrode layer 312 and the electrode protection layer 313 on the surface of the electrode substrate 311. Those layers may be provided through lamination or physical/chemical attachment. Although the electrode protection layer 313 is not indispensable, it is preferable to provide the electrode protection layer 313 for preventing the transmission electrode layer 312 from being sputtered by discharging. The electrode substrate 311 is formed of a dielectric (electric insulator). The electrode protection layer 313 is formed of the dielectric (electric insulator), a semiconductor, or a combination of those materials. The transmission electrode layer 312 is formed on an electrically conductive material, that is, the electric semiconductor or electric conductor. The transmission electrode layer 312 may be at the electrically floating potential, or electrically coupled with the ground potential via circuit as illustrated in FIG. 2A. Alternatively, the transmission electrode layer 312 may be electrically coupled with the high frequency power source 208 via circuit as illustrated in FIG. 2B. The high frequency power source to which the transmission electrode layer is electrically coupled via circuit may be different from the one to which the sample mount table 206 is electrically coupled via circuit, or may be the same as the aforementioned power source. At least a part of the sample mount table 206 may be electrically coupled with the high frequency power source via circuit as illustrated in FIGS. 2A and 2B. At least a part of the sample mount table 206 may be electrically coupled with the ground potential (earth potential) via circuit (not shown in FIGS. 2A and 2B). At least a part of the sample mount table 206 may be electrically at the floating potential.

As described above, the transmission electrode 310 has characteristics to behave as the dielectric (electric insulator) for the discharging electromagnetic wave (at frequency f_{pf} normally in the range from 0.01 GHz to 10 GHz). As a result, the discharging electromagnetic wave 202 does not propagate in the inter-electrode space form the outer side to the inner side (condition of the related art device illustrated in FIG. 25, the cause (2)), and the discharging electromagnetic wave 202 is directly introduced to the discharging region through the transmission electrode 310, thus addressing the problem (B). The transmission electrode 310 has characteristics to behave as the material with the electric conductivity (that is, electric semiconductor or electric conductor) for the electromagnetic wave of ion plasma oscillation (at the frequency fₚᵢ substantially in the range from 2 MHz to 20 MHz), thus addressing the problem (A1).

The transmission electrode 310 has characteristics to behave as the material with electric conductivity (that is, electric semiconductor or electric conductor) for the RF bias electromagnetic wave (frequency f_{rb} normally in the range from 0.01 MHz to 100 MHz, and f_{rb}<f_{pf}), thus addressing the problems of (A2), (C) and (D).

The present invention provides effects for “largely improving the process performance and reliability of the plasma processing apparatus with magnetic field forming member by addressing the problem of cross impedance or voltage drop (potential change) caused by the cross impedance”, and for “largely improving the process performance and reliability of the plasma processing apparatus to make the RF current path resistance value substantially constant irrespective of the sample surface site by oppositely arranging the sample and transmission electrode (transmission electrode layer”.

The present invention also provides the effect for “largely improving stability and reliability of the transmission electrode according to the present invention by introducing the discharging electromagnetic wave to the discharging region with high efficiency using the magnetic field instead of the high frequency antenna”.

The present invention further provides the effect for “providing the high density plasma with ease, high stability, high reliability and high function using the discharging electromagnetic wave at the relatively high frequency f_{pf} in the range from 0.1 GHz to 10 GHz, and the transmission electrode according to the present invention”.

The following description relates to availability of the effect for allowing the transmission electrode “to behave as the dielectric (electric insulator) for the discharging electromagnetic wave (frequency f_{pf} normally in the range from 0.01 GHz to 10 GHz), and to behave as a material with electric conductivity (electric semiconductor or electric conductor) for the RF bias electromagnetic wave (frequency f_{rb} normally in the range from 0.01 MHz to 100 MHz, and f_{rb}<f_{pf}), or the electromagnetic wave of ion plasma oscillation (frequency fₚᵢ substantially in the range from 2 MHz to 20 MHz). The frequency fₚᵢ ranging from 2 MHz to 20 MHz of the electromagnetic wave of ion plasma oscillation is contained in the frequency f_{rb} ranging from 0.01 MHz to 100 MHz of the RF bias electromagnetic wave. So the discussion with respect to the RF bias electromagnetic wave will be used for explaining the electromagnetic wave of ion plasma oscillation.

The method for forming the slit structure is considered for allowing the discharging electromagnetic wave to transmit, and forming the electrode with the electric conductivity with respect to the RF bias current. That is, the slit (gap) formed in the electrode transmits the discharging electromagnetic wave to apply RF current through the continuous section of the electrode. In this method, the plasma and surface treatment characteristics distribute corresponding to the slit structure, thus interfering the uniformity of the surface treatment characteristic in the sample surface. In the present invention, material characteristic and film structure capable of realizing the desired characteristics based on the uniform film structure rather than the slit structure will be described.

The technology to be disclosed herein is the outcome of more detailed examination with respect to conditions satisfied by the transmission electrode compared with Japanese Patent Application Laid-Open Publication No. H10-284299. The present invention was made by quantitatively clarifying the frequency f_{pf} of the discharging electromagnetic wave 302 and the material characteristics of the transmission electrode layer 312 for efficiently applying the technology of the present invention as well as the heat generation issue. The present invention was made by clarifying those effects for “largely improving the process performance and reliability of the plasma processing apparatus with the magnetic forming member by addressing the problem of the cross impedance or the voltage drop (potential change) owing to the cross impedance using the technology of the present invention”, “largely improving the process performance of the plasma processing apparatus and reliability to make the RF current path resistance value constant irrespective of the sample surface position by oppositely arranging the sample and the transmission electrode (transmission electrode layer)”, “largely improving the stability and reliability of the transmission electrode of the present invention by introducing the discharging electromagnetic wave to the discharging region with high efficiency using the magnetic field instead of the high frequency antenna”, and “forming the high density plasma with ease, high stability, high reliability and high function using the discharging electromagnetic wave at the relatively high frequency f_{pf} in the range from 0.1 GHz to 10 GHz, and the transmission electrode of the present invention” in comparison with the technology as disclosed in Japanese Patent Application Laid-open Publication No. H10-284299.

It is assumed that each of the electrode substrate 311 and the electrode protection layer 313 is formed of the dielectric (electric insulator), that is, the electrode substrate 311 and the electrode protection layer 313 transmit the discharging electromagnetic wave. The following description relates to such phenomenon as transmission of the discharging electromagnetic wave through the transmission electrode layer, and the voltage drop caused by the RF current (current induced by the RF bias electromagnetic wave) in the transmission electrode layer. FIG. 3 graphically shows the voltage drop phenomenon caused by the RF current in the transmission electrode layer in the state illustrated in FIG. 2A. The voltage generated by the voltage drop phenomenon will be referred to as the drop voltage. FIG. 3 schematically illustrates the induced voltage, which will be described later.

The phenomenon of transmission of the discharging electromagnetic wave through the transmission electrode layer, and the voltage drop phenomenon caused by the RF current in the transmission electrode layer will be expressed by the following equations (7)-(12).

R_{E}_{_{—}}ₜₑ=exp(−(dₜₑ/δₜₑ₎₎ (7)

R_{W}_{_{—}}ₜₑ=R_{E}_{_{—}}ₜₑ² (8)

δₜₑ=(2/(μₜₑδₜₑ ω̅_{pf}))^{1/2} (9)

ΔV_{rb}_{_{—}}ₜₑ=(ρₜₑiᵢₛ/(4dₜₑ))rₜₑ² (10)

σₜₑ=1/ρₜₑ (11)

ω̅_{pf}=2πf_{pf} (12)

### Where

R_{E}_{_{—}}ₜₑ: magnetic field retention rate in the transmission electrode layer of discharging electromagnetic wave, that is, the ratio of the magnetic field intensity value of the discharging electromagnetic wave between output and input surfaces of the transmission electrode layer;

R_{W}_{_{—}}ₜₑ: power transmission factor of the discharging electromagnetic wave through the transmission electrode layer;

dₜₑ: thickness of transmission electrode layer [m];
δₜₑ: skin thickness of the discharging electromagnetic wave in the transmission electrode layer [m];
μₜₑ: permeability of transmission electrode layer [H/m]=[Vs/(Am)];
σₜₑ: electric conductivity of transmission electrode layer (electric conductivity, specific conductivity) [1/(Ωm)]=[A/(Vm)];
ρₜₑ: resistivity of transmission electrode layer (specific electric resistance) [Ωm], resistivity of material for forming transmission electrode layer;
ω̅_{pf}: angular frequency of discharging electromagnetic wave [rad.Hz]=[rad./s],
f_{pf}: frequency of discharging electromagnetic wave [Hz]=[1/s],
ΔV_{rb}_{_{—}}ₜₑ: RF drop voltage in transmission electrode layer [V], Drop voltage at RF bias electromagnetic voltage (RF voltage) owing to RF current in transmission electrode layer;
iᵢₛ: incident ion current density to the surface of transmission electrode (surface of discharging region) [A/m²], saturated ion current density on transmission electrode surface (surface at discharging region);
rₜₑ: radius of transmission electrode layer [m], or equivalent radius of transmission electrode layer.

The term exp(a) denotes e^{a}, and e denotes a base of natural logarithm (Napier's number). As for the formulae (7), (8) and (9), refer to section of “skin effect” in Iwanami Physical and Chemical Dictionary, 4th version, p. 1060, ed.: Ryougo KUBO et al., IWANAMI SHOTEN, Tokyo, (1987). The formula (7) indicates that the magnetic field intensity of the discharging electromagnetic wave incident to the transmission electrode layer has the skin thickness δₜₑ attenuated exponentially with respect to the propagation distance (that is, thickness dₜₑ of the transmission electrode layer). This indicates that the thickness of the transmission electrode layer dₜₑ sufficiently smaller than the skin thickness δₜₑ allows the discharging electromagnetic wave to transmit the transmission electrode layer with almost no attenuation. The formula (10) is used for obtaining the drop voltage between the center and the outer periphery (edge) of the transmission electrode layer assuming that the transmission electrode layer has a circular shape with radius of rₜₑ, and the ion incidence occurs to the surface (surface at discharging region side) at the current density iᵢₛ uniformly (RF current). If the transmission electrode layer does not have the circular shape, the circle with the same area as that of the transmission electrode layer is assumed such that the radius is defined as the “equivalent radius of the transmission electrode layer”. Supposing that the radius rₜₑ is equal to the “equivalent radius of the transmission electrode layer”, the formula (10) may be substantially established. Normally, the frequency f_{rb} of the RF bias electromagnetic wave or the frequency (oscillation number) fₚᵢ of ion plasma oscillation is lower than the frequency f_{pf} of the discharging electromagnetic wave, and the skin thickness of the RF bias electromagnetic wave or the electromagnetic wave of the ion plasma oscillation is larger than the skin thickness of the discharging electromagnetic wave (δₜₑ of the formula (9)). Accordingly, this makes it possible to regard the transmission electrode layer as a whole as the electric conductor for the RF bias electromagnetic wave and the electromagnetic wave of ion plasma oscillation, thus substantially establishing the formula (10).

In six formulae (7) to (12), 12 variables R_{E}_{_{—}}ₜₑ to rₜₑ are used as described above (π: circular constant). Among the variables, μₜₑ, f_{pf}, iᵢₛ and rₜₑ are known as device and discharge parameters. The number of known variables (4) and the number of relevant formulae (6) are subtracted from the number of variables (12) to obtain the number of the variables (2). The system may be determined by setting those two variables other than the known values. Unless otherwise specified, the calculation and description will be made based on the conditions of “μₜₑ=1.26×10⁻⁶ H/m (vacuum permeability), f_{pf}=1 GHz, iᵢₛ=100 A/m² (=10 mA/cm²), rₜₑ=0.24 m (=240 mm)”. Those conditions will be referred to as “the standard conditions” hereinafter. The standard conditions represent typical and standard values for the general etching device and the surface treatment device. Those values (other than the value rₜₑ) are applicable to the etching device and the surface treatment device with diameter of the sample mount table of 250 mm or larger or further 400 mm or larger.

Assuming that the coordinate system has the thickness dₜₑ of the transmission electrode layer set as the x-axis, and the specific resistance ρₜₑ set as the y-axis, arbitrary point on the coordinate system (the point for defining appropriate two variables dₜₑ and ρₜₑ) defines the whole system. The method for drawing the contour line on the coordinate system while having the value of R_{W}_{_{—}}ₜₑ constant or ΔV_{rb}_{_{—}}ₜₑ constant will be described hereinafter. First of all, the method for drawing the contour line having the value of R_{W}_{_{—}}ₜₑ constant will be described.

The contour line having the value of R_{W}_{_{—}}ₜₑ constant may be drawn by setting dₜₑ as the x-axis and ρₜₑ=ρₜₑ_{_{—}}_{RW} as the y-axis using the following formulae (13) to (16).

from formulae (9) and (11),

ρₜₑ=(δₜₑ²μₜₑ ω̅_{pf})/2 (13)

from formulae (7) and (8),

δₜₑ=−2ₜₑ/ln(R_{W}_{_{—}}ₜₑ) (14)

from formulae (13) and (14),

ρₜₑ=((2dₜₑ/ln(R_{W}_{_{—}}ₜₑ))²μₜₑ ω̅_{pf})/2 (15)

ln (a) denotes a logarithm natural of a. That is, the following formula is established.

ρₜₑ_{_{—}}_{RW}=((2dₜₑ/ln(R_{W}_{_{—}}ₜₑ))²μₜₑ ω̅_{pf})/2 (16)

The method for drawing the contour at constant ΔV_{rb}_{_{—}}ₜₑ will be described. The formula (17) is derived from the formula (10), that is, the formula (18) is established.

ρₜₑ=(4dₜₑΔV_{rb}_{_{—}}ₜₑ)/(iᵢₛrₜₑ²) (17)

ρₜₑ_{_{—}}_{Vrb}=(4dₜₑΔV_{rb}_{_{—}}ₜₑ)/(iᵢₛrₜₑ²) (18)

The dₜₑ is set as the x-axis and ρₜₑ=ρₜₑ_{_{—}}_{Vrb} is set as the y-axis to allow the contour line at constant ΔV_{rb}_{_{—}}ₜₑ to be drawn.

### [Optimum Relationship Between Thickness and Resistivity of Transmission Electrode Layer]

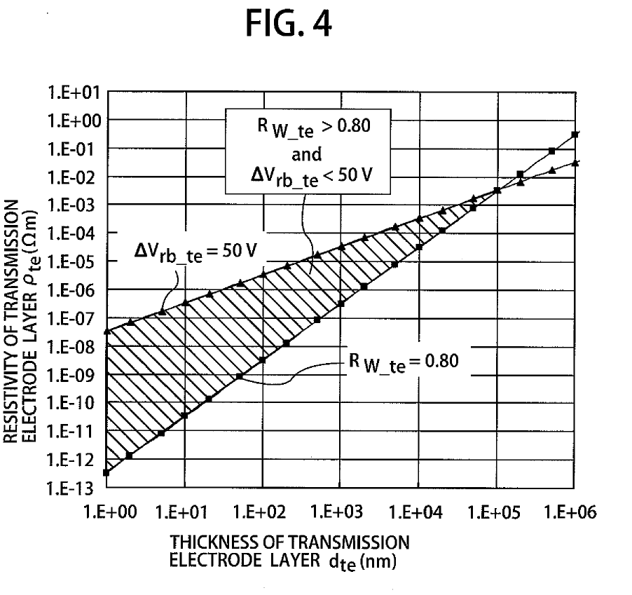

The optimum relationship between the thickness and resistivity of the transmission electrode layer (optimum region defined by the thickness and resistivity of the transmission electrode layer) will be described referring to FIGS. 4 to 7.

FIG. 4 shows a region defined by R_{W}_{_{—}}ₜₑ>0.80 and ΔV_{rb}_{_{—}}ₜₑ<50V on the coordinate system having the thickness dₜₑ of the transmission electrode layer set as x-axis and the resistivity ρₜₑ of the transmission electrode layer set as y-axis. The graph shows the results under the standard condition where “μₜₑ=1.26×10⁻⁶ H/m (vacuum permeability), F_{pf}=1 GHz, iᵢₛ=100 A/m² (=10 mA/cm²), rₜₑ=0.24 m (=240 mm)”. Referring to FIG. 4, the term aEB denotes a×10^{b}, which is applied to the subsequent description. The line indicated by ΔV_{rb}_{_{—}}ₜₑ=50V in FIG. 4 denotes the contour line at ΔV_{xb}_{_{—}}ₜₑ=50V. In the region under the line, the ΔV_{rb}_{_{—}}ₜₑ<50V is established. The contour line of ΔV_{rb}_{_{—}}ₜₑ=50V is drawn based on the formula (B3). The formula (B4) provides the ρₜₑ_{_{—}}_{Vrb} value when the formula (18) is calculated on the basis of ΔV_{rb}_{_{—}}ₜₑ=50V.

ρₜₑ=ρₜₑ_{_{—}}_{Vrb}(ΔV_{rb}_{_{—}}ₜₑ=50V) (B3)

ρₜₑ_{_{—}}_{Vrb}(ΔV_{rb}_{_{—}}ₜₑ=50V) (B4)

ρₜₑ=ρₜₑ_{_{—}}_{RW}(R_{W}_{_{—}}ₜₑ=0.80) (B5)

ρₜₑ_{_{—}}_{RW}(R_{W}_{_{—}}ₜₑ=0.80) (B6)

Likewise the line defined as R_{W}_{_{—}}ₜₑ=0.80 denotes the contour line with R_{W}_{_{—}}ₜₑ=0.80. In the area above the line, the R_{W}_{_{—}}ₜₑ>0.80 is established. The contour line with R_{W}_{_{—}}ₜₑ=0.80 is drawn based on the formula (B5). The formula (B6) provides the ρₜₑ_{_{—}}_{RW} value when the formula (16) is calculated on the basis of R_{W}_{_{—}}ₜₑ=0.80. The region defined by the contour line with ΔV_{rb}_{_{—}}ₜₑ=50V and the contour line with R_{W}_{_{—}}ₜₑ=0.80 (that is, the shaded region shown in FIG. 4) is the region from R_{W}_{_{—}}ₜₑ>0.80 to ΔV_{rb}_{_{—}}ₜₑ<50V. In the “region defined by R_{W}_{_{—}}ₜₑ>0.80 and ΔV_{rb}_{_{—}}ₜₑ<50V”, most of the discharging electromagnetic wave transmits the transmission electrode layer, and RF current induced by the electromagnetic wave of the ion plasma oscillation electrically conducts the transmission electrode layer. That is, in the “region defined by R_{W}_{_{—}}ₜₑ>0.80 and ΔV_{rb}_{_{—}}ₜₑ<50V”, the transmission electrode behaves as the dielectric (electric insulator) for the discharging electromagnetic wave, and behaves as the material with electric conductivity for the RF bias electromagnetic wave or the electromagnetic wave of ion plasma oscillation.

The condition where the power transmission factor R_{W}_{_{—}}ₜₑ of the discharging electromagnetic wave of 80% or higher in the transmission electrode layer is practically appropriate for supplying the discharging electromagnetic wave to the discharging region. The conditions where peak-to-peak voltage (difference between upper peak voltage and lower peak voltage) of the RF bias electromagnetic wave is normally in the range from 500V to 2000V, and the RF drop voltage ΔV_{rb}_{_{—}}ₜₑ is 50V or lower are practically appropriate for applying the RF voltage to the sample mount table 206 and the sample 207.

FIG. 4 shows that the thickness dₜₑ of the transmission electrode layer has to be 1×10⁵ nm=0.1 mm or smaller for the purpose of satisfying the practical condition of “region defined by R_{W}_{_{—}}ₜₑ>0.80 and ΔV_{rb}_{_{—}}ₜₑ<50V”. At the same time, it is obvious that the resistivity ρₜₑ of the transmission electrode layer has to be equal to 3×10⁻³ Ωm=0.3 Ωcm or smaller. The use of electric semiconductor or electric conductor as the material for forming the transmission electrode layer easily sets the resistivity of the transmission electrode layer at ρₜₑ<3×10⁻³ Ωm (=0.3 Ωcm). Such material as Si, SiC, C and composite semiconductor, and the impurity-doped (added) material may be used as the electric semiconductor. Such material as Ti (titanium), Cr (chromium), Ni (nickel), Fe (iron), Al (aluminum), Cu (copper), Ag (silver), Au (gold), an alloy or a material which contains at least a part of the aforementioned metal may be used as the electric conductor. For example, the use of the electric semiconductor establishes the value of the resistivity to ρₜₑ=1×10⁻⁵ Ωm to 10 Ωm (=1×10⁻³ Ωcm to 1×10³ Ωcm). The use of the electric conductor establishes the value of the resistivity to ρₜₑ=1×10⁻⁸ Ωm to 10⁻⁵ Ωm (=1×10⁻⁶ Ωcm to 1×10⁻³ Ωcm). Each resistivity of Ti, Cr, Ni, Fe, Al, Cu, Ag and Au at the room temperature (approximately 20° C.=293K) becomes 4.8×10⁻⁷ Ωm (=4.8×10⁻⁵ Ωcm), 1.98×10⁻⁷ Ωm (=1.9×10⁻⁵ Ωcm), 8×10⁻⁸ Ωm (=8×10⁻⁶ Ωcm), 1×10⁻⁷ Ωm (=1×10⁻⁶ Ωcm), 2.7×10⁻⁸ Ωm (=2.7×10⁻⁶ Ωcm), 1.7×10⁻⁸ Ωm (=1.7×10⁻⁵ Ωcm), 1.6×10⁻⁸ Ωm (=1.6×10⁻⁶ Ωcm), and 2.3×10⁻⁸ Ωm (=2.3×10⁻⁶ Ωcm), respectively. The thickness dₜₑ<1×10⁵ nm (=0.1 mm) of the transmission electrode layer is practically important as the device controlling condition. Meanwhile, the thickness of the transmission electrode layer has to be 10 nm or larger so as to form the film structure (continuous structure). The thickness of the transmission electrode layer has to be 1 nm or larger for forming the film very carefully. In other words, satisfying the condition of formula (19) is necessary as the general condition for the device.

dₜₑ>1nm (19)

Referring to FIG. 4, the condition where the resistivity of the transmission electrode layer is required to be set to 3×10⁻¹³ Ωm (=3×10⁻¹¹ Ωcm) or larger (ρₜₑ>3×10⁻¹³ Ωm (=3×10⁻¹¹ Ωcm)) as the normal device condition.

FIG. 4 shows the results of the region obtained under the standard conditions “μₜₑ=1.26×10⁻⁶ H/m (vacuum permeability), f_{pf}=1 GHz, iᵢₛ=100 A/m² (=10 mA/cm²), rₜₑ=0.24 m (=240 mm)”. They are typical and standard conditions for the etching device and the surface treatment device, and obtained results using FIG. 4 exhibit typical, standard and general values. The following formula (20) is calculated for the purpose of obtaining further general conclusion irrespective of the standard conditions like the case shown in FIG. 4, that is, “μₜₑ=1.26×10⁻⁶ H/m (vacuum permeability), f_{pf}=1 GHz, iᵢₛ=100 A/m² (=10 mA/cm²), rₜₑ=0.24 m (=240 mm)”.

ρₜₑ_{_{—}}_{RW}(R_{W}_{_{—}}ₜₑ=0.80)<ρₜₑ<ρₜₑ_{_{—}}_{Vrb}(ΔV_{rb}_{_{—}}ₜₑ=50V) (20)

The formula (B4) in the formula (20) provides the value of ρₜₑ_{_{—}}_{Vrb} from the formula (18) when ΔV_{rb}_{_{—}}ₜₑ=50V. The formula (B6) provides the value of ρₜₑ_{_{—}}_{RW} from the formula (16) when R_{W}_{_{—}}ₜₑ=0.80. The values such as μₜₑ, f_{pf}, iᵢₛ, and rₜₑ are arbitrary condition values for the device. The region defined by the formula (20) on the coordinate system having the thickness dₜₑ of the transmission electrode layer set as x-axis and the resistivity value ρₜₑ of the transmission electrode layer set as y-axis is the region defined by “R_{W}_{_{—}}ₜₑ>0.80 and ΔV_{rb}_{_{—}}ₜₑ<50V”. The definition and formation of the region are the same as those described referring to FIG. 4. As described referring to FIG. 4, it is practical to add the condition formula (19) for forming the transmission electrode layer into the film structure (continuous structure) to the formula (20).

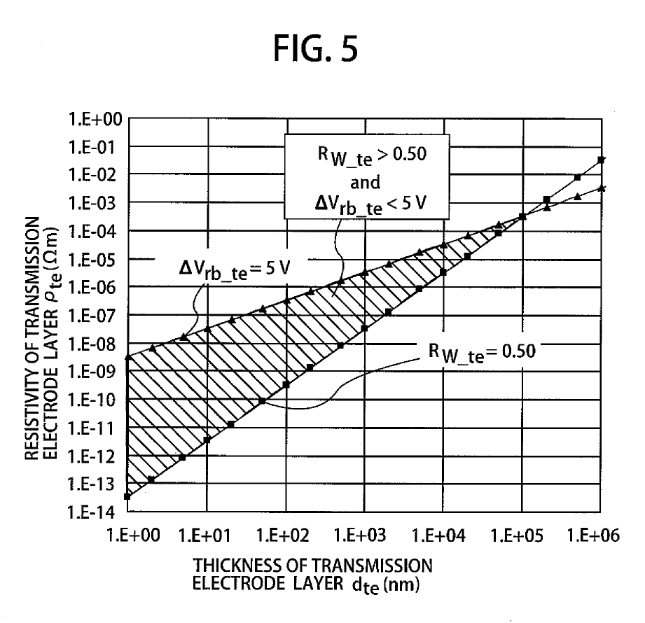

FIG. 5 illustrates the region defined by R_{W}_{_{—}}ₜₑ>0.50 and ΔV_{rb}_{_{—}}ₜₑ<5V on the coordinate system having the thickness dₜₑ of the transmission electrode layer set as x-axis and the resistivity ρₜₑ of the transmission electrode layer set as y-axis. The results of the region obtained under the standard conditions “μₜₑ=1.26×10⁻⁶ H/m (vacuum permeability), f_{pf}=1 GHz, iᵢₛ=100 A/m² (=10 mA/cm²), rₜₑ=0.24 m (=240 mm)” are shown. Referring to FIG. 5, the line indicated by ΔV_{rb-te}=5V denotes the contour line with ΔV_{rb}_{_{—}}ₜₑ=5V. The region under the line corresponds to the one at ΔV_{rb}_{_{—}}ₜₑ<5V. The contour line with ΔV_{rb}_{_{—}}ₜₑ=5V is drawn based on the formula (B7). The formula (B8) provides the value of ρₜₑ_{_{—}}_{Vrb} when ΔV_{rb}_{_{—}}ₜₑ=5 v is set for the formula (18).

ρₜₑ=ρₜₑ_{_{—}}_{Vrb}(ΔV_{rb}_{_{—}}ₜₑ=5V) (B7)

ρₜₑ_{_{—}}_{Vrb}(ΔV_{rb}_{_{—}}ₜₑ=5V) (B8)

ρₜₑ=ρₜₑ_{_{—}}_{RW}(R_{W}_{_{—}}ₜₑ=0.50) (B9)

ρₜₑ_{_{—}}_{RW}(R_{W}_{_{—}}ₜₑ=0.50) (B10)

Likewise, the line indicated by R_{W}_{_{—}}ₜₑ=0.50 denotes the contour line with R_{W}_{_{—}}ₜₑ=0.50. The region above the line corresponds to R_{W}_{_{—}}ₜₑ>0.50. The contour line with R_{W}_{_{—}}ₜₑ=0.50 is drawn based on the formula (B9). The formula (B10) provides the value of ρₜₑ_{_{—}}_{RW} when R_{W}_{_{—}}ₜₑ=0.50 is set in formula (16). The region defined by the contour line with ΔV_{rb}_{_{—}}ₜₑ=5V and the contour line with R_{W}_{_{—}}ₜₑ=0.50 (shaded region in FIG. 5) corresponds to R_{W}_{_{—}}ₜₑ>0.50 and ΔV_{rb}_{_{—}}ₜₑ<5V. In the region corresponding to “R_{W}_{_{—}}ₜₑ>0.50 and ΔV_{rb}_{_{—}}ₜₑ<5V”, most of the discharging electromagnetic wave transmits the transmission electrode layer, and the RF bias electromagnetic wave or the RF current induced by the electromagnetic wave of ion plasma oscillation electrically conduct the transmission electrode layer. In the region corresponding to “R_{W}_{_{—}}ₜₑ>0.50 and ΔV_{rb}_{_{—}}ₜₑ<5V”, the transmission electrode behaves as the dielectric (electric insulator) for the discharging electromagnetic wave, and behaves as the material with electric conductivity for the RF bias electromagnetic wave or the electromagnetic wave of ion plasma oscillation.

The condition where the power transmission factor R_{W}_{_{—}}ₜₑ of the discharging electromagnetic wave in the transmission electrode layer set to 50% or higher is relatively less strict compared with the conditions described referring to FIG. 4. However, they are other practically adequate conditions for supplying the discharging electromagnetic wave to the discharging region. The conditions where the peak-to-peak voltage (difference between the upper peak voltage and the lower peak voltage) of the RF bias electromagnetic wave is normally in the range from 500V to 2000V, and the RF drop voltage ΔV_{rb}_{_{—}}ₜₑ is 5V or lower are stricter compared with those described referring to FIG. 4. However, they are other practically adequate conditions for applying the RF voltage to the sample mount table 206 and the sample 207.

Referring to FIG. 5, the thickness dₜₑ of the transmission electrode layer has to be 1×10⁵ nm=0.1 mm or smaller for the purpose of satisfying the practical conditions of “R_{W}_{_{—}}ₜₑ>0.50 and ΔV_{rb}_{_{—}}ₜₑ<5V”. At the same time, the resistivity value ρₜₑ of the transmission electrode layer has to be 3×10⁻⁴ Ωm=0.03 Ωcm or smaller. The use of electric semiconductor or electric conductor as the material for forming the transmission electrode layer easily sets the resistivity of the transmission electrode layer at ρₜₑ<3×10⁻⁴ Ωcm (=0.03 Ωcm). Examples of the electric semiconductor and the electric conductor are the same as those described referring to FIG. 4. The thickness of the transmission electrode layer dₜₑ<1×10⁵ (0.1 mm) is practically important as the device condition. Meanwhile, the thickness of the transmission electrode layer has to be 1 nm or larger (dₜₑ>1 nm) so as to form the transmission electrode layer to have the film structure (continuous structure) as the normal device condition. As FIG. 5 shows, the resistivity value equal to or larger than 3×10⁻¹⁴ Ωm (=3×10⁻¹² Ωcm) (=ρₜₑ>3×10⁻¹⁴ Ωm (=3×10⁻¹² Ωcm)) is required as the normal device condition.

FIG. 5 shows results of the region obtained under the standard conditions “μₜₑ=1.26×10⁻⁶ H/m (vacuum permeability), f_{pf}=1 GHz, iᵢₛ=100 A/m² (=10 mA/cm²), rₜₑ=0.24 m (=240 mm)”. They are typical and standard conditions for the etching device and the surface treatment device, and obtained results as shown in FIG. 5 exhibit typical, standard and general values. The following formula (21) is calculated for the purpose of obtaining further general conclusion irrespective of the standard conditions like the case shown in FIG. 5, that is, “μₜₑ=1.26×10⁻⁶ H/m (vacuum permeability), f_{pf}=1 GHz, iᵢₛ=100 A/m² (=10 mA/cm²), rₜₑ=0.24 m (=240 mm)”.

ρₜₑ_{_{—}}_{RW}(R_{W}_{_{—}}ₜₑ=0.50)<ρₜₑ<ρₜₑ_{_{—}}_{Vrb}(ΔV_{rb}_{_{—}}ₜₑ=5V) (21)

The formula (B8) in the formula (21) provides the value of ρₜₑ_{_{—}}_{Vrb} from the formula (18) when ΔV_{rb}_{_{—}}ₜₑ=5V. The formula (B10) provides the value of ρₜₑ_{_{—}}_{RW} from the formula (16) when R_{W}_{_{—}}ₜₑ=0.50. The values such as μₜₑ, f_{pf}, iᵢₛ, and rₜₑ are arbitrary condition values for the device. The region defined by the formula (21) on the coordinate system having the thickness dₜₑ of the transmission electrode layer set as x-axis and the resistivity value ρₜₑ of the transmission electrode layer set as y-axis corresponds to “R_{W}_{_{—}}ₜₑ>0.50 and ΔV_{rb}_{_{—}}ₜₑ<5V”. The definition and formation of the region are the same as those described referring to FIG. 5. As described referring to FIG. 5, it is practical to add the condition formula (19) for forming the transmission electrode layer into the film structure (continuous structure) to the formula (21).

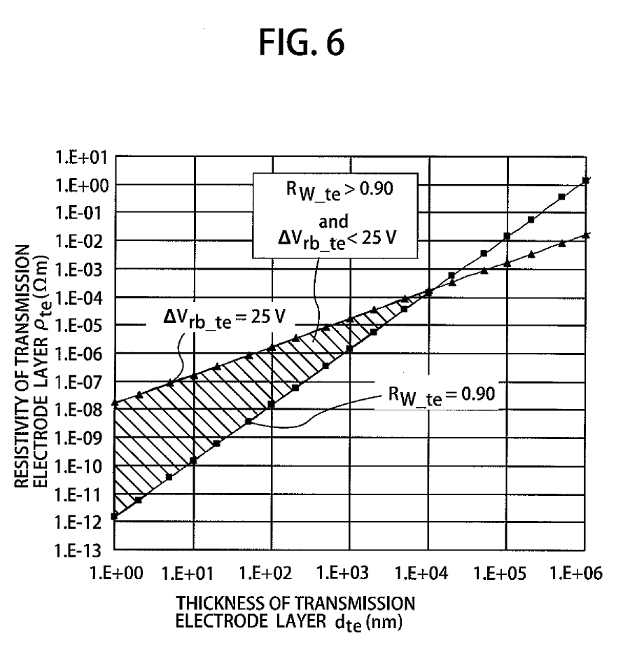

FIG. 6 illustrates the region defined by R_{W}_{_{—}}ₜₑ>0.90 and ΔV_{rb}_{_{—}}ₜₑ<25V on the coordinate system having the thickness dₜₑ of the transmission electrode layer set as x-axis and the resistivity ρₜₑ of the transmission electrode layer set as y-axis. The results of the region obtained under the standard conditions “μₜₑ=1.26×10⁻⁶ H/m (vacuum permeability), f_{pf}=1 GHz, iᵢₛ=100 A/m² (=10 mA/cm²), rₜₑ=0.24 m (=240 mm)” are shown. Referring to FIG. 6, the line indicated by ΔV_{rb-te}=25V denotes the contour line with ΔV_{rb}_{_{—}}ₜₑ=25V. The region under the line corresponds to ΔV_{rb}_{_{—}}ₜₑ<25V. The contour line with ΔV_{rb}_{_{—}}ₜₑ=25V is drawn based on the formula (B11). The formula (B12) provides the value of ρₜₑ_{_{—}}_{Vrb} when ΔV_{rb}_{_{—}}ₜₑ=25 v is set for the formula (18).

ρₜₑ=ρₜₑ_{_{—}}_{Vrb}(ΔV_{rb}_{_{—}}ₜₑ=25V) (B11)

ρₜₑ_{_{—}}_{Vrb}(ρV_{rb}_{_{—}}ₜₑ=25V) (B12)

ρₜₑ=ρₜₑ_{_{—}}_{RW}(R_{W}_{_{—}}ₜₑ=0.90) (B13)

ρₜₑ_{_{—}}_{RW}(R_{W}_{_{—}}ₜₑ=0.90) (B14)

Likewise, the line indicated by R_{W}_{_{—}}ₜₑ=0.90 denotes the contour line with R_{W}_{_{—}}ₜₑ=0.90. The region above the line corresponds to R_{W}_{_{—}}ₜₑ>0.90. The contour line with R_{W}_{_{—}}ₜₑ=0.90 is drawn based on the formula (B13). The formula (B14) provides the value of ρₜₑ_{_{—}}_{RW} when R_{W}_{_{—}}ₜₑ=0.90 is set in formula (16). The region defined by the contour line with ΔV_{rb}_{_{—}}ₜₑ=25V and the contour line with R_{W}_{_{—}}ₜₑ=0.90 (shaded region in FIG. 6) corresponds to R_{W}_{_{—}}ₜₑ>0.90 and ΔV_{rb}_{_{—}}ₜₑ<25V. In the region corresponding to “R_{W}_{_{—}}ₜₑ>0.90 and ΔV_{rb}_{_{—}}ₜₑ<25V”, most of the discharging electromagnetic wave transmits the transmission electrode layer, and the RF bias electromagnetic wave or the RF current induced by the electromagnetic wave of ion plasma oscillation electrically conduct the transmission electrode layer. In the region corresponding to “R_{W}_{_{—}}ₜₑ>0.90 and ΔV_{rb}_{_{—}}ₜₑ<25V”, the transmission electrode has characteristics to behave as the dielectric (electric insulator) for the discharging electromagnetic wave, and behave as the material with electric conductivity for the RF bias electromagnetic wave or the electromagnetic wave of ion plasma oscillation.

The condition where the power transmission factor R_{W}_{_{—}}ₜₑ of the discharging electromagnetic wave in the transmission electrode layer set to 90% or higher is relatively stricter than those described referring to FIG. 4. However, they are other practically adequate conditions for supplying the discharging electromagnetic wave to the discharging region. The conditions where the peak-to-peak voltage (difference between the upper peak voltage and the lower peak voltage) of the RF bias electromagnetic wave is normally in the range from 500V to 2000V, and the RF drop voltage ΔV_{rb}_{_{—}}ₜₑ is 25V or lower are stricter than those described referring to FIG. 4. However, they are other practically adequate conditions for applying the RF voltage to the sample mount table 206 and the sample 207.

Referring to FIG. 6, the thickness dₜₑ of the transmission electrode layer has to be 1×10⁴ nm=0.01 mm or smaller for the purpose of satisfying the practical condition of “R_{W}_{_{—}}ₜₑ>0.90 and ΔV_{rb}_{_{—}}ₜₑ<25V”. At the same time, the resistivity ρₜₑ of the transmission electrode layer has to be 2×10⁻⁴ Ωm=0.02 Ωcm or smaller. The use of electric semiconductor or electric conductor as the material for forming the transmission electrode layer easily sets the resistivity of the transmission electrode layer at ρₜₑ<2×10⁻⁴ Ωm (=0.02 Ωcm). Examples of the electric semiconductor and the electric conductor are the same as those described referring to FIG. 4. The thickness of the transmission electrode layer dₜₑ<1×10⁴ nm (=0.01 mm) is practically important as the device condition. Meanwhile, the thickness of the transmission electrode layer has to be 1 nm or larger (dₜₑ>1 nm) so as to allow the transmission electrode layer to have the film structure (continuous structure). As FIG. 6 shows, the resistivity value of the transmission electrode layer has to be equal to or larger than 2×10⁻¹² Ωm (=2×10⁻¹⁰ Ωcm) (=ρₜₑ>2×10⁻¹² Ωm (=2×10⁻¹⁰ Ωcm)) as the normal device condition.

FIG. 6 shows results of the region obtained under the standard conditions “μₜₑ=1.26×10⁻⁶ H/m (vacuum permeability), f_{pf}=1 GHz, iᵢₛ=100 A/m² (=10 mA/cm²), rₜₑ=0.24 m (=240 mm)”. They are typical and standard conditions for the etching device and the surface treatment device, and obtained results as shown in FIG. 6 exhibit typical, standard and general values. The following formula (22) is calculated for the purpose of obtaining further general conclusion irrespective of the standard conditions like the case shown in FIG. 6, that is, “μₜₑ=1.26×10⁻⁶ H/m (vacuum permeability), f_{pf}=1 GHz, iᵢₛ=100 A/m² (=10 mA/cm²), rₜₑ=0.24 m (=240 mm)”.

ρₜₑ_{_{—}}_{RW}(R_{W}_{_{—}}ₜₑ=0.90)<ρₜₑ<ρₜₑ_{_{—}}_{Vrb}(ΔV_{rb}_{_{—}}ₜₑ=25V) (22)

The formula (B12) in the formula (22) provides the value of ρₜₑ_{_{—}}_{Vrb} from the formula (18) when ΔV_{rb}_{_{—}}ₜₑ=25V. The formula (B14) provides the value of ρₜₑ_{_{—}}_{RW} from the formula (16) when R_{W}_{_{—}}ₜₑ=0.90. The values such as μₜₑ, f_{pf}, iᵢₛ, and rₜₑ are arbitrary device condition values. The region defined by the formula (22) on the coordinate system having the thickness dₜₑ of the transmission electrode layer set as x-axis and the resistivity value ρₜₑ of the transmission electrode layer set as y-axis corresponds to “R_{W}_{_{—}}ₜₑ>0.90 and ΔV_{rb}_{_{—}}ₜₑ<25V”. The definition and formation of the region are the same as those described referring to FIG. 6. As described referring to FIG. 6, it is practical to add the condition formula (19) for forming the transmission electrode layer into the film structure (continuous structure) to the formula (22).

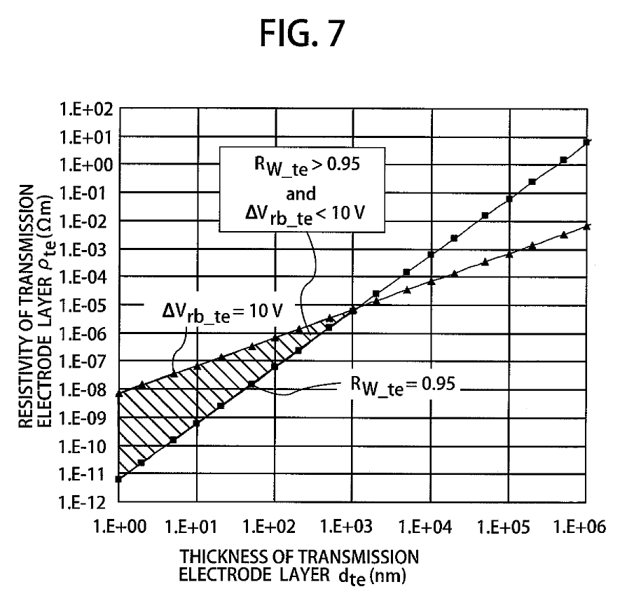

FIG. 7 illustrates the region defined by R_{W}_{_{—}}ₜₑ>0.95 and ΔV_{rb}_{_{—}}ₜₑ<10V on the coordinate system having the thickness dₜₑ of the transmission electrode layer set as x-axis and the resistivity ρₜₑ of the transmission electrode layer set as y-axis. The results of the region obtained under the standard conditions “μₜₑ=1.26×10⁻⁶ H/m (vacuum permeability), f_{pf}=1 GHz, iᵢₛ=100 A/m² (=10 mA/cm²) rₜₑ=0.24 m (=240 mm)” are shown. Referring to FIG. 7, the line indicated by ΔV_{rb-te}=10V denotes the contour line with ΔV_{rb}_{_{—}}ₜₑ=10V. The region under the line corresponds to ΔV_{rb}_{_{—}}ₜₑ<10V. The contour line with ΔV_{rb}_{_{—}}ₜₑ=10V is drawn based on the formula (B15). The formula (B16) provides the value of ρₜₑ_{_{—}}_{Vrb} when ΔV_{rb}_{_{—}}ₜₑ=10V is set for the formula (18).

ρₜₑ=ρₜₑ_{_{—}}_{Vrb}(ΔV_{rb}_{_{—}}ₜₑ=10V) (B15)

ρₜₑ_{_{—}}_{Vrb}(ΔV_{rb}_{_{—}}ₜₑ=10V) (B16)

ρₜₑ=ρₜₑ_{_{—}}_{RW}(R_{W}_{_{—}}ₜₑ=0.95) (B17)

ρₜₑ_{_{—}}_{RW}(R_{W}_{_{—}}ₜₑ=0.95) (B18)

Likewise, the line indicated by R_{W}_{_{—}}ₜₑ=0.95 denotes the contour line with R_{W}_{_{—}}ₜₑ=0.95. The region above the line corresponds to R_{W}_{_{—}}ₜₑ>0.95. The contour line with R_{W}_{_{—}}ₜₑ=0.95 is drawn based on the formula (B17). The formula (B18) provides the value of ρₜₑ_{_{—}}_{RW} when R_{W}_{_{—}}ₜₑ=0.95 is set for the formula (16). The region defined by the contour line with ΔV_{rb}_{_{—}}ₜₑ=10V and the contour line with R_{W}_{_{—}}ₜₑ=0.95 (shaded region in FIG. 7) corresponds to R_{W}_{_{—}}ₜₑ>0.95 and ΔV_{rb}_{_{—}}ₜₑ<10V. In the region corresponding to “R_{W}_{_{—}}ₜₑ>0.95 and ΔV_{rb}_{_{—}}ₜₑ<10V”, most of the discharging electromagnetic wave transmits the transmission electrode layer, and the RF bias electromagnetic wave or the RF current induced by the electromagnetic wave of ion plasma oscillation electrically conducts the transmission electrode layer. In the region corresponding to “R_{W}_{_{—}}ₜₑ>0.95 and ΔV_{rb}_{_{—}}ₜₑ<10V”, the transmission electrode has characteristics to behave as the dielectric (electric insulator) for the discharging electromagnetic wave, and behave as the material with electric conductivity for the RF bias electromagnetic wave or the electromagnetic wave of ion plasma oscillation.

The condition where the power transmission factor R_{W}_{_{—}}ₜₑ of the discharging electromagnetic wave in the transmission electrode layer set to 95% or higher is relatively stricter than the conditions described referring to FIG. 4. However, they are other practically adequate conditions for supplying the discharging electromagnetic wave to the discharging region. The conditions where the peak-to-peak voltage (difference between the upper peak voltage and the lower peak voltage) of the RF bias electromagnetic wave is normally in the range from 500V to 2000V, and the RF drop voltage ΔV_{rb}_{_{—}}ₜₑ is 10V or lower are stricter than those described referring to FIG. 4. However, they are other practically adequate conditions for applying the RF voltage to the sample mount table 206 and the sample 207.

Referring to FIG. 7, the thickness dₜₑ of the transmission electrode layer has to be 1×10³ nm=0.001 mm or smaller for the purpose of satisfying the practical conditions of “R_{W}_{_{—}}ₜₑ>0.95 and ΔV_{rb}_{_{—}}ₜₑ<10V”. At the same time, the resistivity value ρₜₑ of the transmission electrode layer has to be 7×10⁻⁶ Ωm=7×10⁻⁴ Ωcm or smaller. The use of electric conductor as the material for forming the transmission electrode layer easily sets the resistivity of the transmission electrode layer at ρₜₑ<7×10⁻⁶ Ωm (=7×10⁻⁴ Ωcm). The example of the electric conductor is the same as the one described referring to FIG. 4. The thickness of the transmission electrode layer dₜₑ<1×10³ nm (=0.001 mm) is practically important as the device condition. Meanwhile, the thickness of the transmission electrode layer has to be 1 nm or larger (dₜₑ>1 nm) so as to form the transmission electrode layer into the film structure (continuous structure). As FIG. 7 shows, the resistivity value of the transmission electrode layer has to be equal to or larger than 7×10⁻¹² Ωm (=7×10⁻¹⁰ Ωcm) (=ρₜₑ>7×10⁻¹² Ωm (=7×10⁻¹⁰ Ωcm)) as the normal device condition.

FIG. 7 shows results of the region obtained under the standard conditions “μₜₑ=1.26×10⁻⁶ H/m (vacuum permeability), f_{pf}=1 GHz, iᵢₛ=100 A/m² (=10 mA/cm²), rₜₑ=0.24 m (=240 mm)”. They are typical and standard conditions for the etching device and the surface treatment device, and obtained results as shown in FIG. 7 exhibit typical, standard and general values. The following formula (23) is calculated for the purpose of obtaining further general conclusion irrespective of the standard conditions like the case shown in Fig., that is, “μₜₑ=1.26×10⁻⁶ H/m (vacuum permeability), f_{pf}=1 GHz, iᵢₛ=100 A/m² (=10 mA/cm²), rₜₑ=0.24 m (=240 mm)”.

ρₜₑ_{_{—}}_{RW}(R_{W}_{_{—}}ₜₑ=0.95)<ρₜₑ<ρₜₑ_{_{—}}_{Vrb}(ΔV_{rb}_{_{—}}ₜₑ=10V) (23)

The formula (B16) in the formula (23) provides the value of ρₜₑ_{_{—}}_{Vrb} from the formula (18) when ΔV_{rb}_{_{—}}ₜₑ=10V. The formula (B18) provides the value of ρₜₑ_{_{—}}_{RW} from the formula (16) when R_{W}_{_{—}}ₜₑ=0.95. The values such as μₜₑ, f_{pf}, iᵢₛ, and rₜₑ are arbitrary condition values. The region defined by the formula (23) on the coordinate system having the thickness dₜₑ of the transmission electrode layer set as x-axis and the resistivity value ρₜₑ of the transmission electrode layer set as y-axis corresponds to “R_{W}_{_{—}}ₜₑ>0.95 and ΔV_{rb}_{_{—}}ₜₑ<10V”. The definition and formation of the region are the same as those described referring to FIG. 7. As described referring to FIG. 7, it is practical to add the condition formula (19) for forming the transmission electrode layer into the film structure (continuous structure) to the formula (23).

### [Optimum Relationship Between Thickness and Resistivity of Transmission Electrode Layer in Consideration of Heat Value]

The heat value generated by the transmission electrode layer 312 has to be suppressed to be in the practical range for the purpose of realizing the technique of the present invention stably with high reliability. Heat generated in the transmission electrode layer includes the one generated by absorbing a part of the discharging electromagnetic wave therein, and Joule heat caused by the RF current therein. The former will be referred to as electromagnetic absorption heat generation, and the latter will be referred to as Joule heat generation. Formula (24) is established for the electromagnetic absorption heat generation.

Wₕ_{_{—}}_{pf}_{_{—}}ₜₑ=W_{pf}(1−R_{W}_{_{—}}ₜₑ) (24)

where
Wₕ_{_{—}}_{pf}_{_{—}}ₜₑ: maximum power [W] of the electromagnetic absorption heat generation, maximum power of heat generation derived from absorption of discharging electromagnetic wave in the transmission electrode layer
W_{pf}: power [W] of discharging electromagnetic wave, power of discharging incident electromagnetic wave to transmission electrode layer

The formula (25) is established for Joule heat generation.

$${W}_{h\_rb \_te} = \frac{1}{2} {I}_{rb\_te} Δ {V}_{rb\_te} \qquad ( 25 )$$

where
Wₕ_{_{—}}_{rb}_{_{—}}ₜₑ: maximum power [W] of Joule heat generation, maximum power of heat generation derived from Joule heat generation by RF current in the transmission electrode layer
I_{rb}_{_{—}}ₜₑ: Sum total of RF current applied to transmission electrode layer [A]

It is assumed that the transmission electrode layer has a circular shape with radius of rₜₑ, and the RF current (ion current at current density of iᵢₛ) is uniformly applied to the surface (surface at the discharging region side) for calculating the formula (25). If the transmission electrode layer does not have the circular shape, the radius rₜₑ denotes the equivalent radius of the transmission electrode layer. Accordingly, the sum total of heat value in the transmission electrode layer is expressed by the formula (26).

Wₕ_{_{—}}ₜₑ=Wₕ_{_{—}}_{pf}_{_{—}}ₜₑ+Wₕ_{_{—}}_{rb}_{_{—}}ₜₑ (26)

where
Wₕ_{_{—}}ₜₑ: sum total of power generated in transmission electrode layer [W]

Generally, the power derived from the discharging electromagnetic wave is defined as substantially W_{pf}=1000 W. Under the standard condition of iᵢₛ=100 A/m² (=10 mA/cm²) and rₜₑ=0.24 m (=240 mm), relationships of I_{rb}_{_{—}}ₜₑ=18 A≈20 A are established. It is assumed to set Wₕ_{_{—}}ₜₑ<60 W for suppressing the heat value in the transmission electrode layer 312 in the practical range. It is preferable to set R_{W}_{_{—}}ₜₑ>0.97 and ΔV_{rb}_{_{—}}ₜₑ<3V so as to be in the well-balanced state, that is, to satisfy the condition of the formula (B19).

Wₕ_{_{—}}_{pf}_{_{—}}ₜₑ≈Wₕ_{_{—}}_{rb}_{_{—}}ₜₑ (B19)

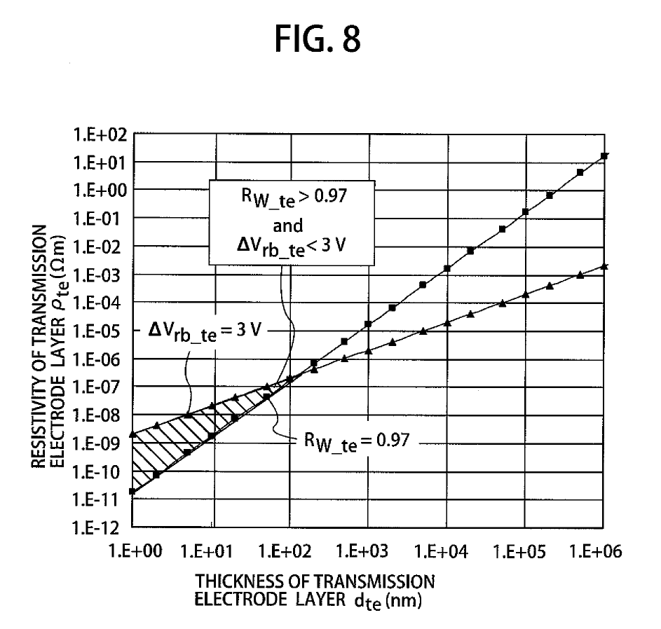

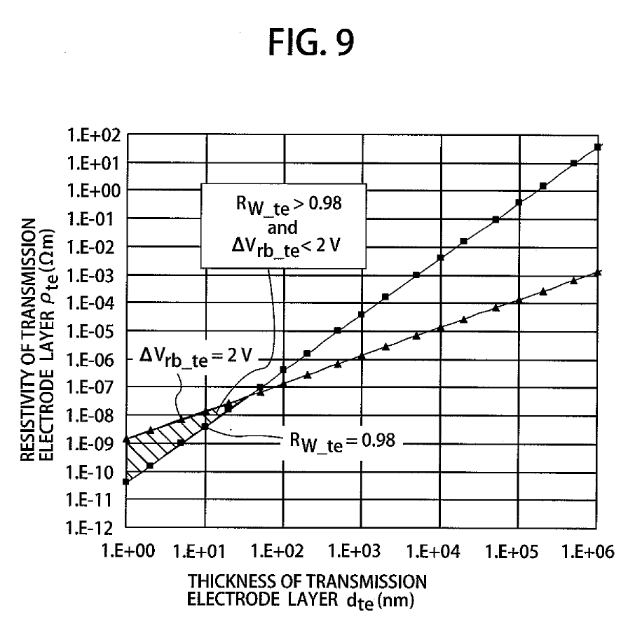

At this time, the relationship of Wₕ_{_{—}}ₜₑ<(1000×(1−0.97)+(1/2)×20×3) W=(30+30) W=60 W is established. Establishment of the relationship Wₕ_{_{—}}ₜₑ<40 W is considered for suppressing the heat value in the transmission electrode layer 312 into the practical range. It is preferable to establish R_{W}_{_{—}}ₜₑ>0.98 and ΔV_{rb}_{_{—}}ₜₑ<2V so as to be in the well-balanced state (condition in formula (B19)). Then the relationship of Wₕ_{_{—}}ₜₑ<(1000×(1−0.98)+(1/2)×20×2) W=(20+20) W=40 W is established. Conditions with respect to the thickness dₜₑ and the resistivity ρₜₑ of the transmission electrode layer for satisfying the aforementioned performance will be examined referring to FIGS. 8 and 9.

FIG. 8 illustrates the region defined by R_{W}_{_{—}}ₜₑ>0.97 and ΔV_{rb}_{_{—}}ₜₑ<3V on the coordinate system having the thickness dₜₑ of the transmission electrode layer set as x-axis and the resistivity ρₜₑ of the transmission electrode layer set as y-axis. The results of the region obtained under the standard conditions “μₜₑ=1.26×10⁻⁶ H/m (vacuum permeability), f_{pf}=1 GHz, iᵢₛ=100 A/m² (=10 mA/cm²), rₜₑ=0.24 m (=240 mm)” are shown. Referring to FIG. 8, the line indicated by ΔV_{rb-te}=3V denotes the contour line with ΔV_{rb}_{_{—}}ₜₑ=3V. The region below the line corresponds to ΔV_{rb}_{_{—}}ₜₑ<3V. The contour line with ΔV_{rb}_{_{—}}ₜₑ=3V is drawn based on the formula (B20). The formula (B21) provides the value of ρₜₑ_{_{—}}_{Vrb} when ΔV_{rb}_{_{—}}ₜₑ=3V is set for the formula (18).

ρₜₑ=ρₜₑ_{_{—}}_{Vrb}(ΔV_{rb}_{_{—}}ₜₑ=3V) (B20)

ρₜₑ_{_{—}}_{Vrb}(ΔV_{rb}_{_{—}}ₜₑ=3V) (B21)

Likewise, the line indicated by R_{W}_{_{—}}ₜₑ=0.97 denotes the contour line with R_{W}_{_{—}}ₜₑ=0.97. The region above the line corresponds to R_{W}_{_{—}}ₜₑ>0.97. The contour line with R_{W}_{_{—}}ₜₑ=0.97 is drawn based on the formula (B22). The formula (B23) provides the value of ρₜₑ_{_{—}}_{RW} when R_{W}_{_{—}}ₜₑ=0.97 is set for the formula (16).

ρₜₑ=ρₜₑ_{_{—}}_{RW}(R_{W}_{_{—}}ₜₑ=0.97) (B22)

ρₜₑ_{_{—}}_{RW}(R_{W}_{_{—}}ₜₑ=0.97) (B23)

The region defined by the contour line with ΔV_{rb}_{_{—}}ₜₑ=3V and the contour line with R_{W}_{_{—}}ₜₑ=0.97 (shaded region in FIG. 8) corresponds to R_{W}_{_{—}}ₜₑ>0.97 and ΔV_{rb}_{_{—}}ₜₑ<3V. In the region corresponding to “R_{W}_{_{—}}ₜₑ>0.97 and ΔV_{rb}_{_{—}}ₜₑ<3V”, most of the discharging electromagnetic wave transmits the transmission electrode layer, and the RF bias electromagnetic wave or the RF current induced by the electromagnetic wave of ion plasma oscillation electrically conducts the transmission electrode layer. In the region corresponding to “R_{W}_{_{—}}ₜₑ>0.97 and ΔV_{rb}_{_{—}}ₜₑ<3V”, the transmission electrode has characteristics to behave as the dielectric (electric insulator) for the discharging electromagnetic wave, and behave as the material with electric conductivity for the RF bias electromagnetic wave or the electromagnetic wave of ion plasma oscillation.

The condition where the power transmission factor R_{W}_{_{—}}ₜₑ of the discharging electromagnetic wave in the transmission electrode layer is set to 97% or higher is relatively stricter than those described referring to FIGS. 4 to 7. However, it is another practically adequate condition for supplying the discharging electromagnetic wave to the discharging region. The conditions where the peak-to-peak voltage (difference between the upper peak voltage and the lower peak voltage) of the RF bias electromagnetic wave is normally in the range from 500V to 2000V, and the RF drop voltage ΔV_{rb}_{_{—}}ₜₑ is 3V or lower are stricter than those described referring to FIGS. 4 to 7. However, they are other practically adequate conditions for applying the RF voltage to the sample mount table 206 and the sample 207. As described above, heat generation in the transmission electrode layer is also considered for those conditions.

FIG. 8 shows that the thickness dₜₑ of the transmission electrode layer has to be 2×10² nm=2000 Å or smaller for the purpose of satisfying the practical condition of “R_{W}_{_{—}}ₜₑ>0.97 and ΔV_{rb}_{_{—}}ₜₑ<3V”. At the same time, it is obvious that the resistivity ρₜₑ of the transmission electrode layer has to be equal to 3×10⁻⁷ Ωm (=3×10⁻⁵ Ωcm) or smaller. The use of electric semiconductor or electric conductor as the material with electric conductivity for forming the transmission electrode layer easily sets the resistivity of the transmission electrode layer at ρₜₑ<3×10⁻⁷ Ωm (=3×10⁻⁵ Ωcm). Especially, it is effective to use the electric conductor. Such material as Cr (chromium), Ni (nickel), Fe (iron), Al (aluminum), Cu (copper), Ag (silver), Au (gold), an alloy or a material which contains at least a part of the aforementioned metals may be used as the electric conductor. So the thickness dₜₑ<2×10² nm=2000 Å becomes practically important as the device condition. Meanwhile, the thickness of 1 nm or larger (dₜₑ>1 nm) is necessary as the normal device condition. As FIG. 8 clearly shows, the resistivity of the transmission electrode layer equal to or larger than 2×10⁻¹¹ Ωm (=2×10⁻⁹ Ωcm) (=ρₜₑ>2×10⁻¹¹ Ωm (=2×10⁻⁹ Ωcm)) is required as the normal device conditions.

FIG. 8 shows the results obtained under the standard conditions “μₜₑ=1.26×10⁻⁶ H/m (vacuum permeability), f_{pf}=1 GHz, iᵢₛ=100 A/m² (=10 mA/cm²), rₜₑ=0.24 m (=240 mm)”. They are typical and standard conditions for the etching device and the surface treatment device, and obtained results as shown in FIG. 8 exhibit typical, standard and general values. The following formula (27) is calculated for the purpose of obtaining further general conclusion irrespective of the standard conditions like the case shown in FIG. 5, that is, “μₜₑ=1.26×10⁻⁶ H/m (vacuum permeability), f_{pf}=1 GHz, iᵢₛ=100 A/m² (=10 mA/cm²), rₜₑ=0.24 m (=240 mm)”.

ρₜₑ_{_{—}}_{RW}(R_{W}_{_{—}}ₜₑ=0.97)<ρₜₑ<ρₜₑ_{_{—}}_{Vrb}(ΔV_{rb}_{_{—}}ₜₑ=3V) (27)

The formula (B21) in the formula (27) provides the value of ρₜₑ_{_{—}}_{Vrb} from the formula (18) when ΔV_{rb}_{_{—}}ₜₑ=3V. The formula (B23) provides the value of μₜₑ_{_{—}}_{RW} from the formula (16) when R_{W}_{_{—}}ₜₑ=0.97. The values such as ρₜₑ, f_{pf}, iᵢₛ, and rₜₑ are arbitrary device condition values. The region defined by the formula (27) on the coordinate system having the thickness dₜₑ of the transmission electrode layer set as x-axis and the resistivity value ρₜₑ of the transmission electrode layer set as y-axis corresponds to “R_{W}_{_{—}}ₜₑ>0.97 and ΔV_{rb}_{_{—}}ₜₑ<3V”. The definition and formation of the region are the same as those described referring to FIG. 8. As described referring to FIG. 8, it is practical to add the condition formula (19) for forming the transmission electrode layer to have the film structure (continuous structure) to the formula (27).

FIG. 9 illustrates the region defined by R_{W}_{_{—}}ₜₑ>0.98 and ΔV_{rb}_{_{—}}ₜₑ<2V on the coordinate system having the thickness dₜₑ of the transmission electrode layer set as x-axis and the resistivity ρₜₑ of the transmission electrode layer set as y-axis. The results of the region obtained under the standard conditions “μₜₑ=1.26×10⁻⁶ H/m (vacuum permeability), f_{pf}=1 GHz, iᵢₛ=100 A/m² (=10 mA/cm²), rₜₑ=0.24 m (=240 mm)” are shown. Referring to FIG. 9, the line indicated by ΔV_{rb-te}=2V denotes the contour line with ΔV_{rb}_{_{—}}ₜₑ=2V. The region below the line corresponds to ΔV_{rb}_{_{—}}ₜₑ<2V. The contour line with ΔV_{rb}_{_{—}}ₜₑ=2V is drawn based on the formula (B24). The formula (B25) provides the value of ρₜₑ_{_{—}}_{Vrb} when ΔV_{rb}_{_{—}}ₜₑ=2V is set for the formula (18).

ρₜₑ=ρₜₑ_{_{—}}_{Vrb}(ΔV_{rb}_{_{—}}ₜₑ=2V) (B24)

ρₜₑ_{_{—}}_{Vrb}(ΔV_{rb}_{_{—}}ₜₑ=2V) (B25)

Likewise, the line indicated by R_{W}_{_{—}}ₜₑ=0.98 denotes the contour line with R_{W}_{_{—}}ₜₑ=0.98. The region above the line corresponds to R_{W}_{_{—}}ₜₑ>0.98. The contour line with R_{W}_{_{—}}ₜₑ=0.98 is drawn based on the formula (B26). The formula (B27) provides the value of ρₜₑ_{_{—}}_{RW} when R_{W}_{_{—}}ₜₑ=0.98 is set for the formula (16).

ρₜₑ=ρₜₑ_{_{—}}_{RW}(R_{W}_{_{—}}ₜₑ=0.98) (B26)

ρₜₑ_{_{—}}_{RW}(R_{W}_{_{—}}ₜₑ=0.98) (B27)

The region defined by the contour line with ΔV_{rb}_{_{—}}ₜₑ=2V and the contour line with R_{W}_{_{—}}ₜₑ=0.98 (shaded region in FIG. 9) corresponds to R_{W}_{_{—}}ₜₑ>0.98 and ΔV_{rb}_{_{—}}ₜₑ<2V. In the region corresponding to “R_{W}_{_{—}}ₜₑ>0.98 and ΔV_{rb}_{_{—}}ₜₑ<2V”, most of the discharging electromagnetic wave transmits the transmission electrode layer, and the RF bias electromagnetic wave or the RF current induced by the electromagnetic wave of ion plasma oscillation electrically conducts the transmission electrode layer. In the region corresponding to “R_{W}_{_{—}}ₜₑ>0.98 and ΔV_{rb}_{_{—}}ₜₑ<2V”, the transmission electrode has characteristics to behave as the dielectric (electric insulator) for the discharging electromagnetic wave, and behave as the material with electric conductivity for the RF bias electromagnetic wave or the electromagnetic wave of ion plasma oscillation.

The condition where the power transmission factor R_{W}_{_{—}}ₜₑ of the discharging electromagnetic wave in the transmission electrode layer set to 98% or higher is relatively stricter than the conditions described referring to FIGS. 4 to 7. However, it is another practically adequate condition for supplying the discharging electromagnetic wave to the discharging region. The conditions where the peak-to-peak voltage (difference between the upper peak voltage and the lower peak voltage) of the RF bias electromagnetic wave is normally in the range from 500V to 2000V, and the RF drop voltage ΔV_{rb}_{_{—}}ₜₑ is 2V or lower are stricter than those described referring to FIGS. 4 to 7. However, they are other practically adequate conditions for applying the RF voltage to the sample mount table 206 and the sample 207. As described above, heat generation in the transmission electrode layer is also considered for those conditions.

FIG. 9 shows that the thickness dₜₑ of the transmission electrode layer has to be 30 nm=300 Å or smaller for the purpose of satisfying the practical condition of “R_{W}_{_{—}}ₜₑ>0.98 and ΔV_{rb}_{_{—}}ₜₑ<2V”. At the same time, it is obvious that the resistivity ρₜₑ of the transmission electrode layer has to be equal to 3×10⁻⁸ Ωm=3×10⁻⁶ Ωcm or smaller. The use of electric semiconductor or electric conductor as the material with electric conductivity for forming the transmission electrode layer easily sets the resistivity of the transmission electrode layer at ρₜₑ<3×10⁻⁸ Ωm (=3×10⁻⁶ Ωcm). Especially, it is effective to use the electric conductor. Such material as Al (aluminum), Cu (copper), Ag (silver), Au (gold), an alloy or a material which contains at least a part of the aforementioned metal group may be used as the electric conductor. So the thickness dₜₑ<30 nm=300 Å becomes practically important as the device condition. Meanwhile, the thickness of 1 nm or larger (dₜₑ>1 nm) is necessary as the normal device condition. As FIG. 9 clearly shows, the resistivity of the transmission electrode layer equal to or larger than 5×10⁻¹¹ Ωm (=5×10⁻⁹ Ωcm) (=ρₜₑ>5×10⁻¹¹ Ωm (=5×10⁻⁹ Ωcm)) is required as the normal device conditions.

FIG. 9 shows results of the region obtained under the standard conditions “μₜₑ=1.26×10⁻⁶ H/m (vacuum permeability), f_{pf}=1 GHz, iᵢₛ=100 A/m² (=10 mA/cm²), rₜₑ=0.24 m (=240 mm)”. They are typical and standard conditions for the etching device and the surface treatment device, and obtained results as shown in FIG. 9 exhibit typical, standard and general values. The following formula (28) is established irrespective of the standard conditions like the case shown in FIG. 9, that is, “μₜₑ=1.26×10⁻⁶ H/m (vacuum permeability), f_{pf}=1 GHz, iᵢₛ=100 A/m² (=10 mA/cm²), rₜₑ=0.24 m (=240 mm)”.

ρₜₑ_{_{—}}_{RW}(R_{W}_{_{—}}ₜₑ=0.98)<ρₜₑ<ρₜₑ_{_{—}}_{Vrb}(ΔV_{rb}_{_{—}}ₜₑ=2V) (28)

The formula (B25) in the formula (28) provides the value of ρₜₑ_{_{—}}_{Vrb} from the formula (18) when ΔV_{rb}_{_{—}}ₜₑ=2V. The formula (B27) provides the value of ρₜₑ_{_{—}}_{RW} from the formula (16) when R_{W}_{_{—}}ₜₑ=0.98. The values such as μₜₑ, f_{pf}, iᵢₛ, and rₜₑ are arbitrary device condition values. The region defined by the formula (28) on the coordinate system having the thickness dₜₑ of the transmission electrode layer set as x-axis and the resistivity value ρₜₑ of the transmission electrode layer set as y-axis corresponds to “R_{W}_{_{—}}ₜₑ>0.98 and ΔV_{rb}_{_{—}}ₜₑ<2V”. The definition and formation of the region are the same as those described referring to FIG. 9. As described referring to FIG. 9, it is practical to add the condition formula (19) for forming the transmission electrode layer to have the film structure (continuous structure) to the formula (28).

[Contour Line on Coordinate System of Thickness and Resistivity of Transmission Electrode Layer at Constant R_{W}_{_{—}}ₜₑ]

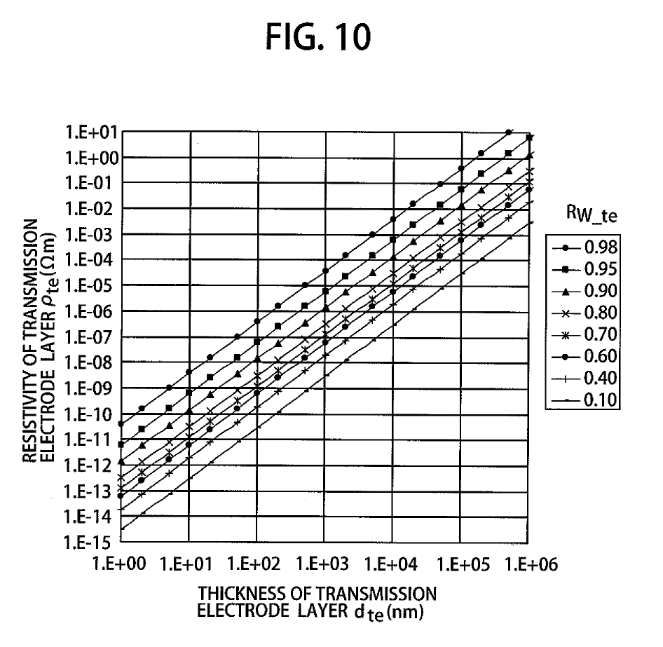

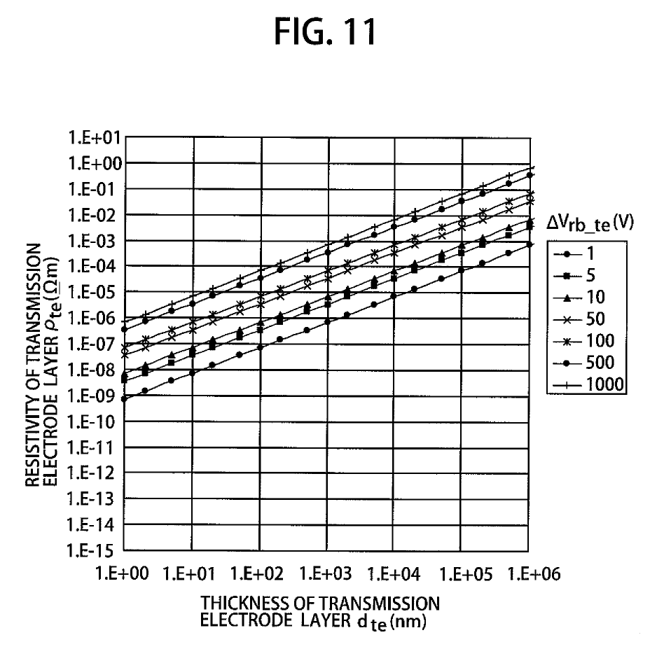

Each contour line on the coordinate system having the thickness dₜₑ of the transmission electrode layer set as x-axis, and having the resistivity of the transmission electrode set as y-axis while holding R_{W}_{_{—}}ₜₑ and ΔV_{rb}_{_{—}}ₜₑ constant, respectively referring to FIGS. 10-11.

FIG. 10 illustrates contour lines at constant R_{W}_{_{—}}ₜₑ on the coordinate system taking the thickness dₜₑ of the transmission electrode layer as x-axis, and the resistivity ρₜₑ of the transmission electrode layer as y-axis. The contour line is drawn based on the method expressed by the formula (16). The graph shows the results of the region obtained under the standard conditions “μₜₑ=1.26×10⁻⁶ H/m (vacuum permeability), f_{pf}=1 GHz, iᵢₛ=100 A/m² (=10 mA/cm²), rₜₑ=0.24 m (=240 mm)”. The respective lines on the graph correspond to R_{W}_{_{—}}ₜₑ values sequentially from the top, that is, 0.98, 0.95, 0.90, 0.80, 0.70, 0.60, 0.40, and 0.10.

FIG. 11 illustrates contour lines at constant ΔV_{rb}_{_{—}}ₜₑ on the coordinate system taking the thickness dₜₑ of the transmission electrode layer as x-axis, and the resistivity ρₜₑ of the transmission electrode layer as y-axis. The contour line is drawn based on the method expressed by the formula (18). The graph shows results of the region obtained under the standard conditions “μₜₑ=1.26×10⁻⁶ H/m (vacuum permeability), f_{pf}=1 GHz, iᵢₛ=100 A/m² (=10 mA/cm²), rₜₑ=0.24 m (=240 mm)”. The respective lines on the graph correspond to ΔV_{rb}_{_{—}}ₜₑ values sequentially from the top, that is, 1000V, 500V, 100V, 50V, 10V, 5V and 1V.

[Dependency of Power Transmission Factor R_{W}_{_{—}}ₜₑ and RF Drop Voltage ΔV_{rb}_{_{—}}ₜₑ on Thickness dₜₑ of Transmission Electrode Layer]

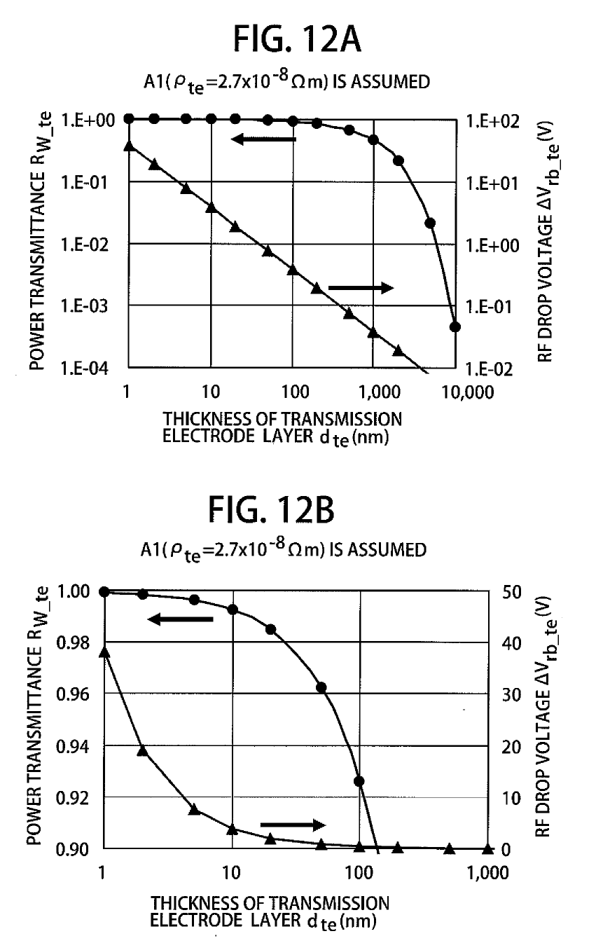

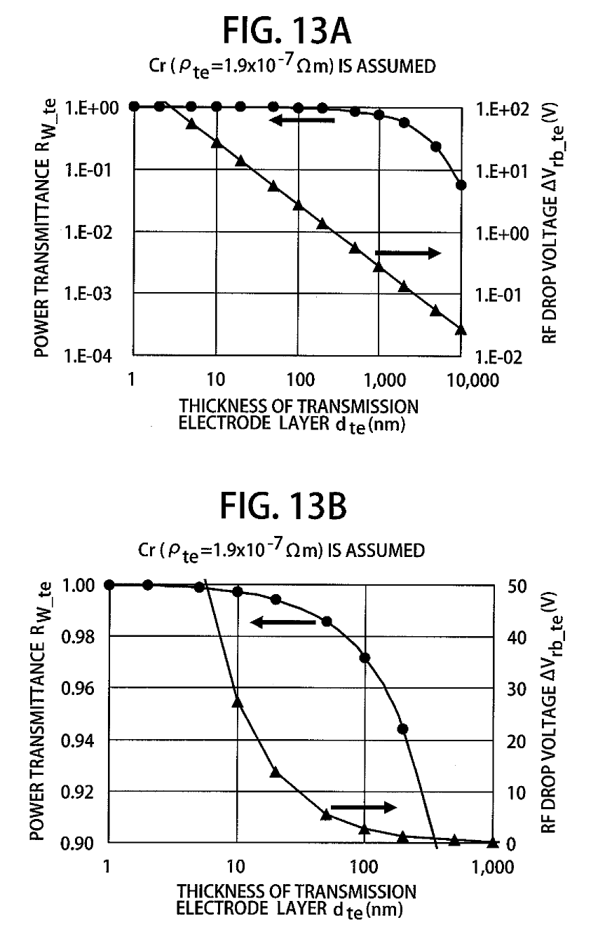

The dependency of power transmission factor R_{W}_{_{—}}ₜₑ and RF drop voltage ΔV_{xb}_{_{—}}ₜₑ on the thickness dte of the transmission electrode layer will be described referring to FIGS. 12A to 13.

Each of FIGS. 12A and 12B shows dependency of the power transmission factor R_{W}_{_{—}}ₜₑ and RF drop voltage ΔV_{rb}_{_{—}}ₜₑ on the thickness dₜₑ of the transmission electrode layer. The results shown in the graph are obtained on the assumption that Al (resistivity ρₜₑ=2.7×10⁻⁸ Ωm) is used as the material for forming the transmission electrode layer. The formulae (7), (8) and (9) are calculated for obtaining the power transmission factor R_{W}_{_{—}}ₜₑ, and the formula (10) is calculated for obtaining the ΔV_{rb}_{_{—}}ₜₑ. The graph shows the results obtained under the standard conditions “μₜₑ=1.26×10⁻⁶ H/m (vacuum permeability), f_{pf}=1 GHz, iᵢₛ=100 A/m² (=10 mA/cm²), rₜₑ=0.24 m (=240 mm)”. FIG. 12B is formed by enlarging a specific portion of the region shown in FIG. 12A. FIGS. 12A and 12B clearly show that each value of the thickness dₜₑ of the transmission electrode layer has to be equal to or smaller than 1000 nm (dₜₑ<1000 nm), 300 nm (dₜₑ<300 m), 150 nm (dₜₑ<150 nm), 70 nm (dₜₑ<70 nm), and 25 nm (dₜₑ<25 nm) for establishing the power transmission factor R_{W}_{_{—}}ₜₑ to be equal to or higher than 50% (R_{W}_{_{—}}ₜₑ>50), 80% (R_{W}_{_{—}}ₜₑ>80), 90% (R_{W}_{_{—}}ₜₑ>0.90), 95% (R_{W}_{_{—}}ₜₑ>0.95) and 98% (R_{W}_{_{—}}ₜₑ>0.98), respectively. Especially the performance resulting from the condition of dₜₑ<150 nm and R_{W}_{_{—}}ₜₑ>0.90 is practically adequate. Each performance resulting from the condition of dₜₑ<70 nm and R_{W}_{_{—}}ₜₑ>0.95 or the condition of dₜₑ<25 nm and R_{W}_{_{—}}ₜₑ>0.98 may improve the power transmission factor as another practical performance. Meanwhile, the thickness of the transmission electrode layer has to be set to 1 nm or larger, that is, establishment of the formula (15) is required to form the transmission electrode layer to have the film structure (continuous structure). At this time, the RF drop voltage ΔV_{rb}_{_{—}}ₜₑ is equal to 38V or lower (ΔV_{rb}_{_{—}}ₜₑ<38V). In consideration of the conditions where the peak-to-peak voltage (difference between the upper peak voltage and the lower peak voltage) of the RF bias electromagnetic wave is normally in the range from 500V to 2000V, the performance resulting from the RF drop voltage ΔV_{rb}_{_{—}}ₜₑ (ΔV_{rb}_{_{—}}ₜₑ<38V) is practically adequate condition for applying the RF voltage to the sample mount table 206 and the sample 207. The results shown in FIGS. 12A and 12B are obtained on the assumption of the use of Al (resistivity ρₜₑ=2.7×10⁻⁸ Ωm) as the material for forming the transmission electrode layer. If the material for forming the transmission electrode layer has the resistivity ρₜₑ of approximately 3×10⁻⁸ Ωm (for example, 1×10⁻⁸ Ωm<ρₜₑ<1×10⁻⁷ Ωm), substantially the same performance as the one described herein with respect to the results referring to FIGS. 12A and 12B may be realized.

Each of FIGS. 13A and 13B shows dependency of the power transmission factor R_{W}_{_{—}}ₜₑ and RF drop voltage ΔV_{rb}_{_{—}}ₜₑ on the thickness dₜₑ of the transmission electrode layer. The results shown in the graph are obtained on the assumption that Cr (resistivity ρₜₑ=1.9×10⁻⁷ Ωm) is used as the material for forming the transmission electrode layer. The formulae (7), (8) and (9) are calculated for obtaining the power transmission factor R_{W}_{_{—}}ₜₑ, and the formula (10) is calculated for obtaining the ΔV_{rb}_{_{—}}ₜₑ. The graph shows the results obtained under the standard conditions “μₜₑ=1.26×10⁻⁶ H/m (vacuum permeability), f_{pf}=1 GHz, iᵢₛ=100 A/m² (=10 mA/cm²), rₜₑ=0.24 m (=240 mm)”. FIG. 13B is formed by enlarging a specific portion of the region shown in FIG. 13A. FIGS. 13A and 133 clearly show that each value of the thickness dₜₑ of the transmission electrode layer has to be equal to or smaller than 2500 nm (dₜₑ<2500 nm), 1000 nm (dₜₑ<1000 nm), 400 nm (dₜₑ<400 nm), 200 nm (dₜₑ<200 nm), and 70 nm (dₜₑ<70 nm) for establishing the power transmission factor R_{W}_{_{—}}ₜₑ to be equal to or higher than 50% (R_{W}_{_{—}}ₜₑ>0.50), 80% (R_{W}_{_{—}}ₜₑ>0.80), 90% (R_{W}_{_{—}}ₜₑ>0.90), 95% (R_{W}_{_{—}}ₜₑ>0.95), and 98% (R_{W}_{_{—}}ₜₑ>0.98), respectively. Especially the performance resulting from the condition of dₜₑ<400 nm and R_{W}_{_{—}}ₜₑ>0.90 is practically adequate. Each performance resulting from the condition of dₜₑ<200 nm and R_{W}_{_{—}}ₜₑ>0.95 or the condition of dₜₑ<70 nm and R_{W}_{_{—}}ₜₑ>0.98 may improve the power transmission factor as another practical performance. Meanwhile, the thickness of the transmission electrode layer has to be set to 10 nm or larger to form the transmission electrode layer to have the film structure (continuous structure) without paying attention to the film formation. At this time, the RF drop voltage ΔV_{rb}_{_{—}}ₜₑ is equal to 27V or lower (ΔV_{rb}_{_{—}}ₜₑ<27V). In consideration of the conditions where the peak-to-peak voltage (difference between the upper peak voltage and the lower peak voltage) of the RF bias electromagnetic wave is normally in the range from 500V to 2000V, the performance resulting from the RF drop voltage ΔV_{rb}_{_{—}}ₜₑ (ΔV_{rb}_{_{—}}ₜₑ<27V) is practically adequate for applying the RF voltage to the sample mount table 206 and the sample 207. The results shown in FIGS. 13A and 13B are obtained on the assumption that Cr (resistivity ρₜₑ=1.9×10⁻⁷ Ωm) is used as the material for forming the transmission electrode layer. If the material for forming the transmission electrode layer has the resistivity ρₜₑ of approximately 2×10⁻⁷ Ωm (for example, 1×10⁻⁷ Ωm<ρₜₑ<1×10⁻⁸ Ωm), substantially the same performance as the one described herein with respect to the results referring to FIGS. 13A and 13B may be realized.

[Dependency of Power Transmission Factor R_{W}_{_{—}}ₜₑ and Resistivity ρₜₑ on Thickness dₜₑ of Transmission Electrode Layer]

The values of R_{W}_{_{—}}ₜₑ and ρₜₑ will be obtained from the system defined by the respective values of ΔV_{rb}_{_{—}}ₜₑ and dₜₑ. The formula (29) is established from the formula (10), and formulae (30) to (31) are established from the formulae (11) and (9), respectively.

ρₜₑ=(4dₜₑΔV_{rb}_{_{—}}ₜₑ)/(iᵢₛrₜₑ²) (29)

δₜₑ=(δₜₑ_{_{—}}_{fn}dₜₑ)^{1/2} (30)

δₜₑ_{_{—}}_{fn}=(8ΔV_{rb}_{_{—}}ₜₑ)/(iᵢₛrₜₑ²μₜₑ ω̅_{pf}) (31)

where
δₜₑ_{_{—}}_{fn}: basic skin thickness [m] of discharging electromagnetic wave in the transmission electrode layer

Formula (32) is derived from the formulae (7) and (8) as follows.

R_{W}_{_{—}}ₜₑ=exp(−2(dₜₑ/δₜₑ_{_{—}}_{fn})^{1/2}) (32)

With the formula (31), the value of δₜₑ_{_{—}}_{fn} is determined by the device, discharge, natural parameter and the value of ΔV_{rb}_{_{—}}ₜₑ. The formulae (29) and (32) are calculated to obtain values of ρₜₑ and R_{W}_{_{—}}ₜₑ using ΔV_{rb}_{_{—}}ₜₑ and dₜₑ.

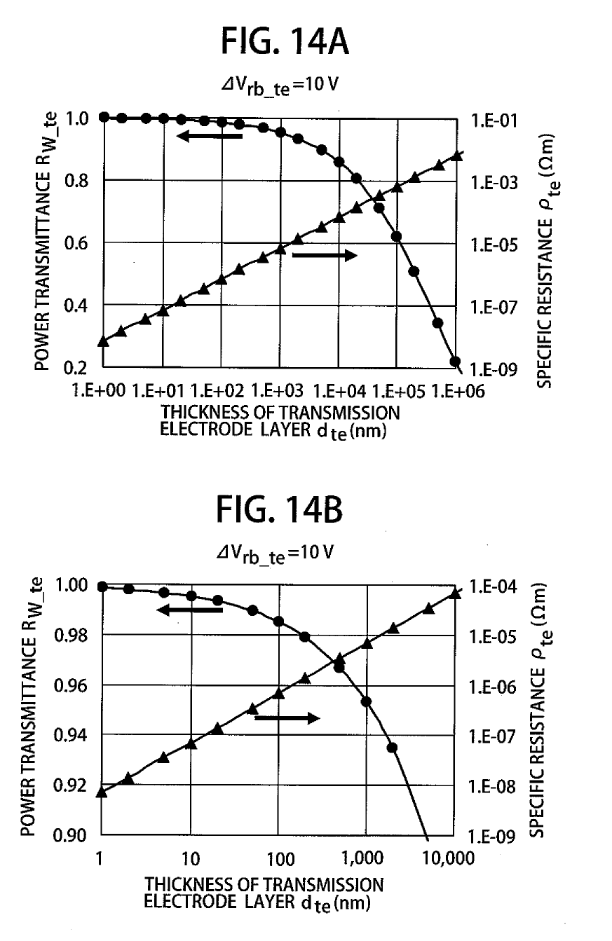

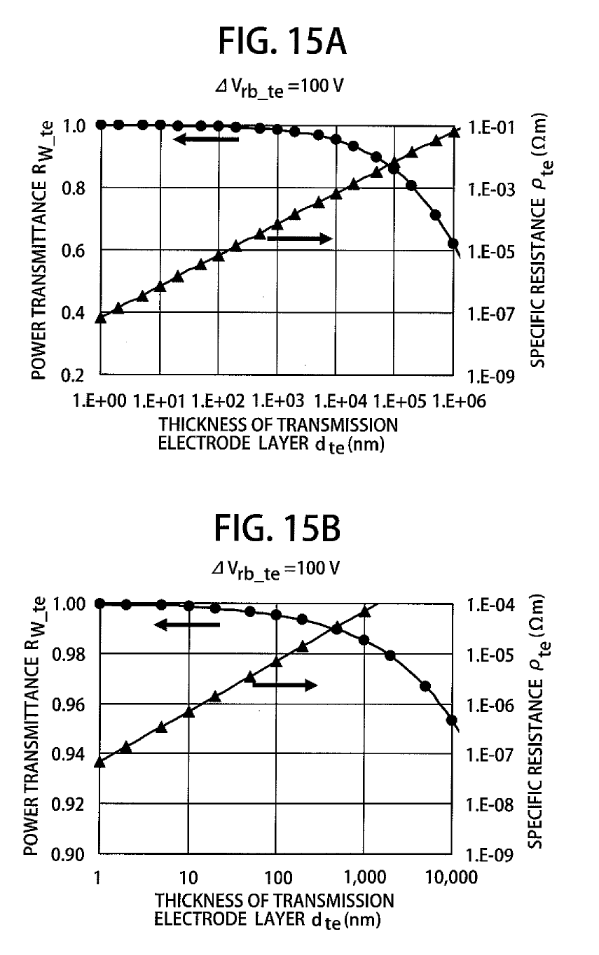

Dependency of the power transmission factor R_{W}_{_{—}}ₜₑ and resistivity ρₜₑ on the thickness dₜₑ of the transmission electrode layer derived from the above-described formulae (28) and (32) will be described referring to FIGS. 14A to 15B.

Each of FIGS. 14A and 14B shows the dependency of the power transmission factor R_{W}_{_{—}}ₜₑ and the resistivity ρₜₑ on the thickness dₜₑ of the transmission electrode layer at the RF drop voltage ΔV_{rb}_{_{—}}ₜₑ=10V. The power transmission factor R_{W}_{_{—}}ₜₑ and the resistivity ρₜₑ are obtained by calculating formulae (32) and (29) while having RF drop voltage ΔV_{rb}_{_{—}}ₜₑ set to 10V. The graph shows the results obtained under the standard conditions “μₜₑ=1.26×10⁻⁶ H/m (vacuum permeability), f_{pf}=1 GHz, iᵢₛ=100 A/m² (=10 mA/cm²), rₜₑ=0.24 m (=240 mm)”. The condition of the RF drop voltage ΔV_{rb}_{_{—}}ₜₑ set to 10V is practically adequate for applying the RP voltage to the sample mount table 206 and the sample 207 when considering that the peak-to-peak voltage (difference between the upper peak voltage and the lower peak voltage) of the RF bias electromagnetic wave is normally in the range from 500V to 2000V. FIG. 14B is formed by enlarging a portion of the region shown in FIG. 14A. FIGS. 14A and 14B clearly show that each value of the thickness dₜₑ and the resistivity ρₜₑ of the transmission electrode layer has to be set to dₜₑ<0.2 mm and ρₜₑ<1×10⁻³ Ωm, dₜₑ<0.02 mm and ρₜₑ<1×10⁻⁴ Ωm, dₜₑ<5000 nm and ρₜₑ<3×10⁻⁵ Ωm, dₜₑ<1200 nm and ρₜₑ<1×10⁻⁵ Ωm, and dₜₑ<200 nm and ρₜₑ<1.5×10⁻⁶ Ωm for establishing the power transmission factor R_{W}_{_{—}}ₜₑ to be equal to or higher than 50% (R_{W}_{_{—}}ₜₑ>0.50), 80% (R_{W}_{_{—}}ₜₑ>0.80), 90% (R_{W}_{_{—}}ₜₑ>0.90), 95% (R_{W}_{_{—}}ₜₑ>0.95), and 98% (R_{W}_{_{—}}ₜₑ>0.98), respectively. Especially the performance resulting from the condition of dₜₑ<5000 nm, ρₜₑ<3×10⁻⁵ Ωm, and R_{W}_{_{—}}ₜₑ>0.90 is practically adequate. Further each performance resulting from the condition of dₜₑ<1200 nm, ρₜₑ<1×10⁻⁵ Ωm, and R_{W}_{_{—}}ₜₑ>0.95, or dₜₑ<200 nm, ρₜₑ<1.5×10⁻⁶ Ωm, and R_{W}_{_{—}}ₜₑ>0.98 is another practically adequate one for improving the power transmission factor. Meanwhile, the thickness of the transmission electrode layer has to be 1 nm or larger, that is, calculating the formula (19) is required as the normal device condition for forming the transmission electrode layer to have the film structure (continuous structure). At this time, the resistivity ρₜₑ of the transmission electrode layer has to be set to 7×10⁻⁹ Ωm or higher (ρₜₑ>7×10⁻⁹ Ωm).

Each of FIGS. 15A and 15B shows dependency of the power transmission factor R_{W}_{_{—}}ₜₑ and the resistivity ρₜₑ on the thickness dₜₑ of the transmission electrode layer at the RF drop voltage ΔV_{rb}_{_{—}}ₜₑ=100V. The power transmission factor R_{W}_{_{—}}ₜₑ and the resistivity ρₜₑ are obtained by calculating formulae (32) and (29) while having the RF drop voltage ΔV_{rb}_{_{—}}ₜₑ set to 100V. The graph shows the results obtained under the standard conditions “μₜₑ=1.26×10⁻⁶ H/m (vacuum permeability), f_{pf}=1 GHz, iᵢₛ=100 A/m² (=10 mA/cm²), rₜₑ=0.24 m (=240 mm)”. The condition of the RF drop voltage ΔV_{rb}_{_{—}}ₜₑ set to 100V is another practically adequate one for applying the RP voltage to the sample mount table 206 and the sample 207 when considering that the peak-to-peak voltage (difference between the upper peak voltage and the lower peak voltage) of the RF bias electromagnetic wave is normally in the range from 500V to 2000V. FIG. 15B is formed by enlarging a specific portion of the region shown in FIG. 15A. FIGS. 15A and 15B clearly show that each value of the thickness dₜₑ and the resistivity ρₜₑ of the transmission electrode layer has to be set to dₜₑ<0.2 mm and ρₜₑ<1×10⁻² Ωm, dₜₑ<0.05 mm and ρₜₑ<3×10⁻³ Ωm, dₜₑ<0.01 mm and ρₜₑ<3×10⁻⁴ Ωm and dₜₑ<2000 nm and ρₜₑ<1×10⁻⁴ Ωm for establishing each power transmission factor R_{W}_{_{—}}ₜₑ to be equal to or higher than 80% (R_{W}_{_{—}}ₜₑ>0.80), 90% (R_{W}_{_{—}}ₜₑ>0.90), 95% (R_{W}_{_{—}}ₜₑ>0.95), and 98% (R_{W}_{_{—}}ₜₑ>0.98), respectively. Especially the performance resulting from the condition of dₜₑ<0.05 nm, ρₜₑ<3×10⁻³ Ωm, and R_{W}_{_{—}}ₜₑ>0.90 is practically adequate. Furthermore, each performance resulting from the condition of dₜₑ<0.01 mm, ρₜₑ<3×10⁻⁴ Ωm, and R_{W}_{_{—}}ₜₑ>0.95, or dₜₑ<2000 nm, ρₜₑ<1×10⁻⁴ Ωm, and R_{W}_{_{—}}ₜₑ>0.98 is another practically adequate one for improving the power transmission factor. Meanwhile, the thickness of the transmission electrode layer has to be 1 nm or larger, that is, calculation of the formula (19) is required as the normal device condition for forming the transmission electrode layer to have the film structure (continuous structure). At this time, the resistivity ρₜₑ of the transmission electrode layer has to be set to 7×10⁻⁸ Ωm or higher (ρₜₑ>7×10⁻⁸ Ωm).

### [Thickness of Electrode Protection Layer]

The thickness of the electrode protection layer will be described. As explained referring to FIG. 2, it is preferable to coat the surface (surface at the discharging region side) of the transmission electrode layer 312 with the electrode protection layer 313. The electrode protection layer is formed of a dielectric (electric insulator), a semiconductor, or a combination thereof. In the case where the electrode protection layer is formed of the dielectric (electric insulator), the electrode protection layer is charged by the RF current (incidence of charged particles such as ion and electron) from discharging to the surface of the electrode protection layer. The charging modulates the RF bias electromagnetic wave potential (RF voltage) applied to the transmission electrode layer. It is preferable to suppress such modulation as least as possible to efficiently apply the RF voltage applied to the transmission electrode layer to the surface of the transmission electrode (surface at the discharging region side), that is, the surface of the electrode protection layer (surface at the discharging region side). In the case where the electrode protection layer is formed of the semiconductor, or the combination of the semiconductor and the dielectric, the aforementioned charging influence may be reduced, but never eliminated.

The voltage to be modulated through charging will be referred to as RF inductive voltage ΔV_{rb}_{_{—}}ᵢₚ of the electrode protection layer. The RF inductive voltage ΔV_{rb}_{_{—}}ᵢₚ will be described with respect to the case where the electrode protection layer is formed of the dielectric. In the aforementioned case, the value of the RF inductive voltage ΔV_{rb}_{_{—}}ᵢₚ is maximized. Following formulae (33) to (36) are established with respect to the RF inductive voltage ΔV_{rb}_{_{—}}ᵢₚ.

ΔV_{rb}_{_{—}}ᵢₚ=Δqᵢₚ/cᵢₚ (33)

Δqᵢₚ=iᵢₛ(1/fₜₕ)×0.9 (34)

cᵢₚ=∈ᵢₚ/dᵢₚ (35)

∈ᵢₚ=kᵢₚ∈₀ (36)

where
ΔV_{rb}_{_{—}}ᵢₚ: RF inductive voltage [V] in electrode protection layer, amplitude of inductive voltage owing to accumulation of RF current charge in the electrode protection layer;
Δqᵢₚ: accumulated charge density [C/m²] on the surface of the electrode protection layer, amplitude of charge density accumulated on the surface of the electrode protection layer
cᵢₚ: capacity density of electrode protection layer [F/m2].
f_{rb}: frequency of RF bias electromagnetic wave [Hz=[1/s]]
∈ᵢₚ: dielectric constant of electrode protection layer [CV⁻¹ m⁻¹]
dᵢₚ: thickness of electrode protection layer [m]
∈₀: dielectric constant of vacuum [CV⁻¹ m⁻¹] ∈₀=8.85×10⁻¹² CV⁻¹ m⁻¹,
kᵢₚ: specific dielectric constant of electrode protection layer

In the formula (34), it is assumed that the ion is applied into the surface of the electrode protection layer for a period at RF bias electromagnetic wave frequency (1/f_{rb}) of 90%=0.9. The value of 90% is adequate for the normal RF bias application condition.

Assuming the representative conditions where f_{rb}=13.56 MHz, iᵢₛ=100 A/m² (=10 mA/cm²), kᵢₚ=4.5 (the use of quartz (SiO₂) is assumed as the material for forming the electrode protection layer), and dᵢₚ=1×10⁻³ m (=1 mm), the value of ΔV_{rb}_{_{—}}ᵢₚ=167V is obtained. Assuming another representative conditions where f_{rb}=13.56 MHz, iᵢₛ=10 A/m² (=1 mA/cm²), kᵢₚ=4.5 (the use of quartz (SiO₂) is assumed as the material for forming the electrode protection layer), and dᵢₚ=1×10⁻² m (=103 m), the value of ΔV_{rb}_{_{—}}ᵢₚ=167V is obtained. Assuming still another representative conditions where f_{rb}=13.56 MHz, iᵢₛ=10 A/m² (=1 mA/cm²), kᵢₚ=4.5 (the use of quartz (SiO₂) is assumed as the material for forming the electrode protection layer), and dᵢₚ=1×10⁻³ m (=1 mm), the value of ΔV_{rb}_{_{—}}ᵢₚ=17V is obtained. Those values of ΔV_{rb}_{_{—}}ᵢₚ are practically adequate for applying the RP voltage to the sample mount table 206 and the sample 207 when considering that the peak-to-peak voltage (difference between the upper peak voltage and the lower peak voltage) of the RF bias electromagnetic wave is normally in the range from 500V to 2000V. In consideration of the aforementioned factors, the value of the thickness dᵢₚ of the electrode protection layer of 10 mm or smaller (dᵢₚ<10 mm) is adequate device condition. Furthermore, the thickness dᵢₚ of the electrode protection layer of 1 mm or smaller (dᵢₚ<1 mm) is another adequate device condition for further suppressing the value of ΔV_{rb}_{_{—}}ᵢₚ to be lower.

Meanwhile, the surface of the electrode protection layer 313 (surface at the discharging region side) is exposed to discharging, and the thickness dᵢₚ of the electrode protection layer is gradually decreased owing to reaction with the discharging or sputtering through the discharging accompanied with the use of the apparatus. The conditions where the thickness dᵢₚ of the electrode protection layer of 0.001 mm or larger (dᵢₚ>0.001 mm), 0.01 mm or larger (dᵢₚ>0.01 mm), or further 0.1 mm or larger (dᵢₚ>0.1 mm) becomes the practical device condition. The larger the thickness dᵢₚ of the electrode protection layer becomes, the longer the practical life of the electrode protection layer becomes.

### [Thickness of Electrode Substrate]

The thickness of the electrode substrate 311 will be described. In the case where the transmission electrode 310 is used to bear the differential pressure between the atmospheric pressure and the pressure inside the processing chamber (when the transmission electrode 310 serves as the pressure wall), the electrode substrate 311 is required to bear the differential pressure. For this, the thickness of the electrode substrate 311 is increased to be approximately 5 mm to 20 mm under the normal (processing chamber with the normal size) condition. Meanwhile, if the transmission electrode 310 does not have to bear the differential pressure, it is appropriate to set the thickness of the electrode substrate 311 to approximately 1 mm to 10 mm.

### Second Embodiment

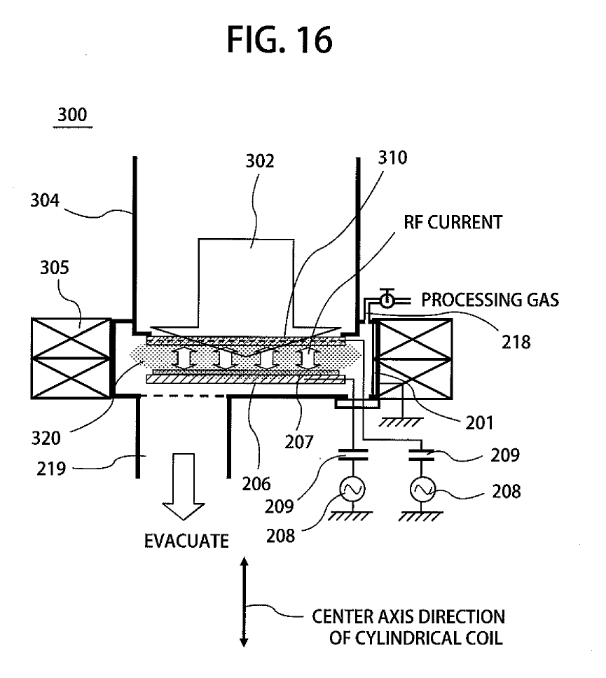

A plasma processing apparatus according to a second embodiment of the present invention will be present described. FIG. 16 is a vertical sectional view of a plasma processing apparatus 300 according to the second embodiment of the invention. In this example, the discharging electromagnetic wave 302 is supplied through the circular waveguide 304. A laminated transmission electrode (or transmission electrode layer) 310 is provided between the circular waveguide 304 and the processing chamber 201. The transmission electrode 310 is provided opposite the sample mount surface of the sample mount table 206 inside the processing chamber 201. As a result, the transmission electrode 310 and the sample 207 are oppositely arranged to form the opposed electrode structure. The magnetic field forming member 305 is provided around the processing chamber 201.

The apparatus according to the second embodiment is different from that of the first embodiment in that the transmission electrode layer 312 is electrically coupled with the high frequency power source 208 via circuit. The high frequency power source with which the transmission electrode layer is electrically coupled via circuit may be the same as or different from the one with which the sample mount table 206 is electrically coupled via circuit.

Structures of the other elements such as the transmission electrode 310 are the same as those of the first embodiment as shown in FIGS. 2A, 2B, and 4 to 15B.

Likewise the apparatus of the first embodiment, apparatus of the second embodiment obviously provides effects for “largely improving process performance and reliability of the plasma processing apparatus with magnetic field forming member by addressing the problem of cross impedance or voltage drop (potential change) owing to cross impedance”, and “making the path resistance value of RF current constant to improve process performance and reliability of the plasma processing apparatus by oppositely arranging the sample and transmission electrode (or transmission electrode layer).

Likewise the apparatus of the first embodiment, the apparatus of the second embodiment obviously provides the effect for “largely improving stability and reliability of the transmission electrode of the present invention by highly efficiently introducing the discharging electromagnetic wave to the discharging region using the magnetic field instead of the high frequency antenna”.

Likewise the apparatus of the first embodiment, the apparatus of the second embodiment obviously provides the effect for “forming the high density plasma with ease, high stability, high reliability and high function by using the discharging electromagnetic wave at the relatively high frequency f_{pf} in the range from 0.1 GHz to 10 GHz and the transmission electrode according to the present invention”.

### Third Embodiment

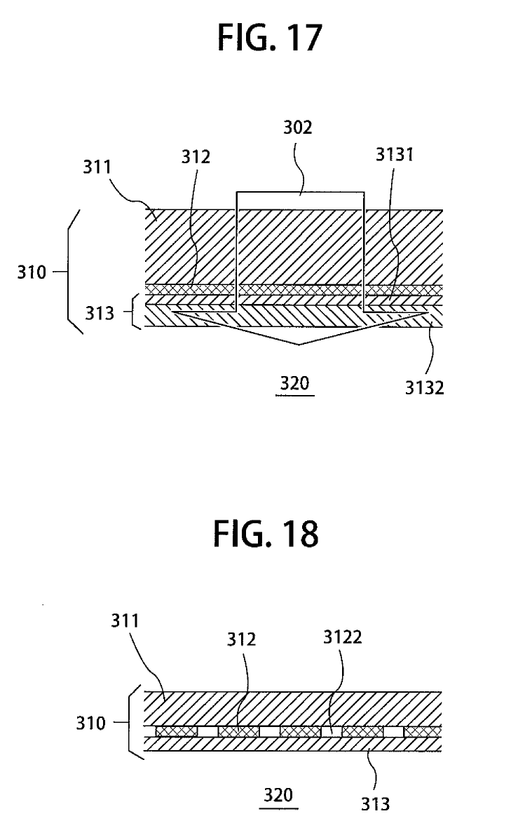

A plasma processing apparatus according to a third embodiment of the present invention will be described. FIG. 17 is a partially sectional view of the transmission electrode 310. The discharging electromagnetic wave 302 (or a part of the discharging electromagnetic wave) is supplied to the discharging region 320 from the electrode substrate 311 through the transmission electrode layer 312 and the electrode protection layer 313. The transmission electrode 310 is employed instead of the one for the plasma processing apparatus 300 according to the first or the second embodiment.

The apparatus of this embodiment includes an electrode protection lower layer 3131 and an electrode protection upper layer 3132 at least as a part of the components of the electrode protection layer. The electrode protection lower layer 3131 is laminated on the surface of the transmission electrode layer 312 (surface at the discharging region side), and the electrode protection upper layer 3132 is formed or provided on the electrode protection lower layer 3131. The electrode protection lower layer 3131 may be laminated through a CVD (Chemical Vapor Deposition) process or plasma CVD (Plasma Chemical Vapor Deposition) process. The electrode protection upper layer 3132 may be formed or provided through the CVD (Chemical vapor Deposition) process, the plasma CVD (Plasma Chemical Vapor Deposition) process, a thermal spray processing, a fixing process using adhesive agent, and a physical fixing process. In order to protect the transmission electrode layer 312, the electrode protection layer 313 has to be provided in tight contact with the transmission electrode layer 312 as much as possible. In order to secure the life of the transmission electrode 310, the electrode protection layer as thick as possible has to be provided. Normally, it is technically difficult to form the thick electrode protection layer in tight contact with the transmission electrode layer. As the electrode protection layer 313 is structured to have the electrode protection lower layer 3131 and the electrode protection upper layer 3132 separately to overcome the aforementioned technical difficulty.

In the basic structure of the transmission electrode according to the present invention as shown in FIGS. 2A and 2B, and the third embodiment of the present invention shown in FIG. 17, how the transmission electrode layer 312 is strongly fixed onto the electrode substrate 311 is the important issue because of possibility that the thermal stress resulting from heating of the transmission electrode to cause thermal stress between the transmission electrode layer 312 and the electrode substrate 311. The use of the material which can be strongly adhered to the electrode substrate (normally formed of quartz, glass or alumina) as the material for forming the transmission electrode layer 312 is one approach to overcome the aforementioned problem. Such material as W, Ti, Cr and Ni may be employed as the one for forming the transmission electrode layer. Alternatively, before forming the transmission electrode layer 312, the surface of the electrode substrate 311 for forming the transmission electrode layer 312 may be preliminarily roughened (concave-convex is formed on the surface). The roughened surface of the electrode substrate 311 allows the transmission electrode layer 312 to be fixedly adhered to the transmission substrate 311. The surface may be roughened through sandblasting. The method for preventing generation of the thermal stress between the transmission electrode layer 312 and the electrode substrate 311 is effective for addressing the problem. Specifically, it is effective to minimize the difference in the thermal expansion coefficient between the transmission electrode layer 312 and the electrode substrate 311. Furthermore, it is effective to provide a thermal expansion coefficient buffer layer between the transmission electrode layer 312 and the electrode substrate 311 for generally changing the thermal expansion coefficient.

The thermal stress also occurs between the transmission electrode layer 312 and the electrode protection lower layer 3131 of the structure shown in FIG. 17. Accordingly, the material with excellent adhesion property with respect to the transmission electrode layer 312 is suitable as the material for forming the electrode protection lower layer 3131. Normally, such material as silicon oxide (quartz, SiO₂) and aluminum oxide (alumina, Al₂O₃) is suitable for forming such layer.

The electrode protection layer 313 of the basic structure of the transmission electrode as illustrated in FIGS. 2A and 2B, and the electrode protection upper layer 3132 of the structure illustrated in FIG. 17 function in preventing the transmission electrode layer 312 from being sputtered by the plasma. For example, such dielectric as silicon oxide (quartz, SiO2), alumina (Al₂O₃), and yttria (Al₂O₃) is suitable for the use as the electrode protection layer 313 or the electrode protection upper layer 3132 with the aforementioned function. It is possible to use the semiconductor, for example, silicon (Si), SiC, C and a composite semiconductor. The semiconductor may be doped (added) with impurity element. Alternatively, the material formed by combining the dielectric and the semiconductor may be employed.

### Fourth Embodiment

A plasma processing apparatus according to a fourth embodiment of the present invention will be described. FIG. 18 is a partially sectional view of the transmission electrode 310. The discharging electromagnetic wave 302 (or a part of the discharging electromagnetic wave) is supplied to the discharging region 320 from the electrode substrate 311 through the transmission electrode layer 312 and the electrode protection layer 313. The transmission electrode 310 is employed instead of the one for the plasma processing apparatus 300 according to the first or the second embodiment.

In the structure according to the present embodiment, at least a transmission electrode layer missing region 3122 is formed in at least one point of the transmission electrode layer 312. The transmission electrode layer missing region 3122 denotes the region with lack of material with electric conductivity for forming the transmission electrode layer 312 in the transmission electrode layer. The transmission electrode layer missing region 3122 may be arbitrarily shaped, for example, circular, rectangular, linear (slit-like, line threads) and the like. The dielectric material (electric insulator) may be filled in the transmission electrode layer missing region 3122, or it may be left hollowed or vacuum state without filling the missing region. The use of the transmission electrode layer 312 provides the following practical effects. That is, the resistivity ρₜₑ of the transmission electrode layer 312 may be effectively controlled. As the resistivity of the transmission electrode layer missing region 3122 is considerably large, normal resistivity of the transmission electrode layer 312 may be controlled by allowing the transmission electrode layer missing region 3122 to be remained in the transmission electrode layer 312. This may conduct fine control with respect to properties of the transmission electrode 310 (that is, transmission factor of the discharging electromagnetic wave and the voltage drop feature by the RF current). The state inside the processing chamber (state of the sample or discharging state) may be observed through the transmission electrode layer 312. Generally, the transmission electrode layer formed of the material with electric conductivity is unclear. As the clear transmission electrode layer missing region 3122 is kept in the transmission electrode layer 312, the inner state of the processing chamber is made observable. The dielectric (electric insulator) for forming the transmission electrode layer missing region 3122, the hollow state or the vacuum state may be easily made optically transparent.

### Fifth Embodiment

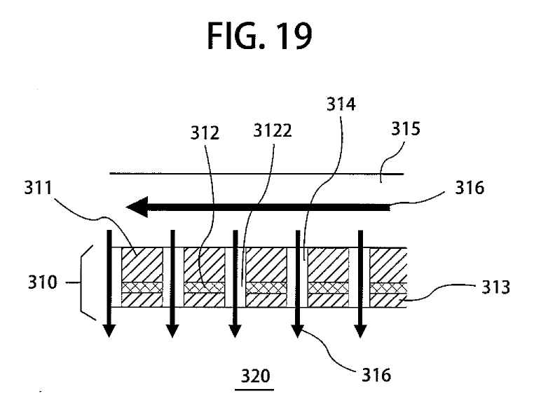

A plasma processing apparatus according to a fifth embodiment of the present invention will be described. FIG. 19 is a partially sectional view of the transmission electrode 310. The discharging electromagnetic wave 302 (or a part of the discharging electromagnetic wave) is supplied to the discharging region 320 from a gas flow passage 315 through the electrode substrate 311, the transmission electrode layer 312, and the electrode protection layer 313. The transmission electrode 310 and the gas flow passage 315 are employed in place of the transmission electrode 310 for the plasma processing apparatus 300 according to the first or the second embodiment.

The apparatus of the present embodiment is structured to allow at least a part of the etching gas (processing gas) to be introduced into the processing chamber 201 through the transmission electrode layer missing region 3122. Specifically, a gas inlet 314 is formed in the transmission electrode 310 to communicate the gas flow passage 315 formed above the transmission electrode 310 with a processing gas outlet 218. The etching gas (or a part thereof) is introduced into the processing chamber 201 through the processing gas outlet 218, the gas flow passage 315, and the gas outlet 314 in the transmission electrode 310. The portion where the gas outlet 314 is overlapped with the transmission electrode layer 312 is formed as the transmission electrode layer missing region 3122. The gas outlet 314 (that is, the transmission electrode layer missing region 3122 overlapped therewith) is formed as a hollow portion. The etching gas (or a part thereof) is introduced into the processing chamber 201 through the gas flow passage 315 and the gas outlet 314. The gas flow 316 as shown in FIG. 19 graphically represents the flow of the etching gas. The structure and function of the present embodiment allow the etching gas (or a part thereof) to be uniformly introduced into the processing chamber 201. Alternatively, the structure and function of the present embodiment are capable of controlling the flow distribution of the etching gas (or a part thereof) inside the processing chamber 201.

In the apparatus of the present embodiment according to FIG. 19, the gas outlet 314 is formed to be overlapped with the transmission electrode layer 312 (or penetrating). It is clearly understood that the gas outlet 314 and the transmission electrode layer 312 may be formed in different divided regions of the transmission electrode 310.

### Sixth Embodiment

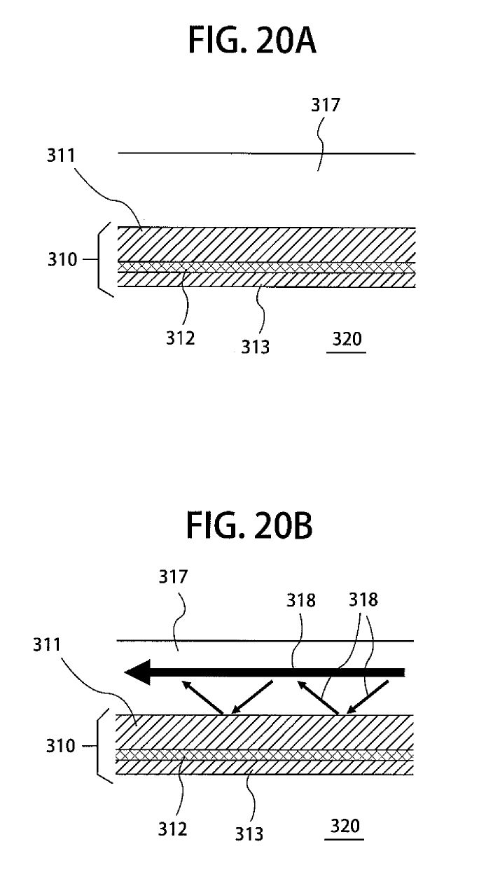

A plasma processing apparatus according to a sixth embodiment of the present invention will be described. FIG. 20A is a partially sectional view of the transmission electrode 310 and its periphery. The discharging electromagnetic wave 302 (or a part thereof) is supplied to the discharging region 320 from a transmission electrode cooling member 317 through the electrode substrate 311, the transmission electrode layer 312, and the electrode protection layer 313. The transmission electrode 310 and the transmission electrode cooling member 317 are employed in place of the transmission electrode 310 for the plasma processing apparatus 300 according to the first or the second embodiment.

The apparatus according to the present embodiment includes a device or a function for cooling or controlling temperatures of the transmission electrode 310. FIG. 20A illustrates the transmission electrode cooling member 317 as the device or the function for cooling the transmission electrode 310. FIG. 20B illustrates the state of the transmission electrode cooling member 317 which functions in cooling the transmission electrode with a cooling gas flow 318.

The apparatus according to the present embodiment includes the device and function for providing the practical functions as described below. Since the transmission electrode layer 312 is formed of the material with electric conductivity, the discharging electromagnetic wave 302 is partially absorbed in the transmission electrode layer 312. The RF current serves to generate heat in the transmission electrode layer 312. As a result, the transmission electrode layer 312 and further the transmission electrode 310 as a whole are heated. The device and function according to the embodiment are capable of controlling temperatures of the transmission electrode 310. For example, flow rate or the temperature of the cooling gas flow 318 is controlled so as to conduct the temperature control of the transmission electrode 310. It is especially effective to add the function for measuring the temperature of the transmission electrode 310, and to control the flow rate or the temperature of the cooling gas flow 318 based on the measurement results. Control of the temperature of the transmission electrode 310 is important not only for the period for which the plasma is simply processed (processing period) but also for the period between the plasma processing periods (that is, waiting time). The control enhances reliability and stability of the device and processing.

### Seventh Embodiment

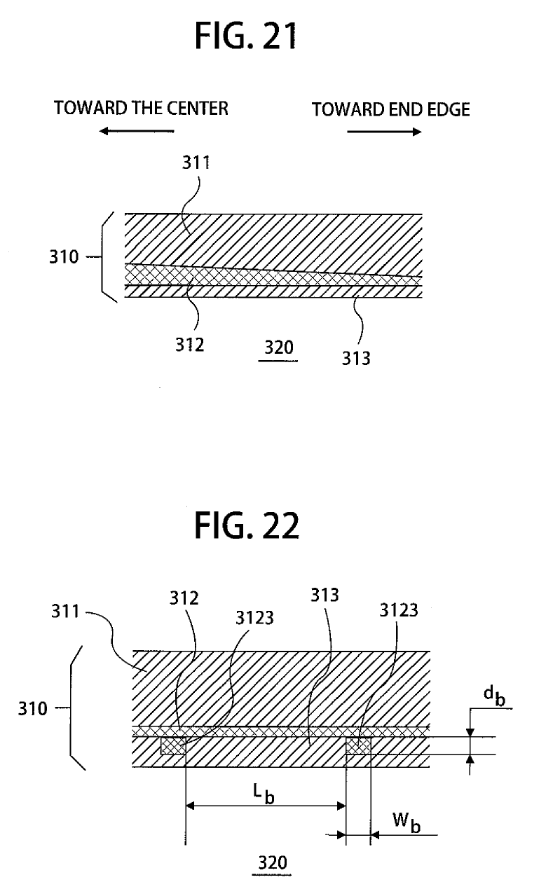

A plasma processing apparatus according to a seventh embodiment of the present invention will be described. FIG. 21 is a partially sectional view of the transmission electrode 310. The discharging electromagnetic wave 302 (or a part thereof) is supplied to the discharging region 320 from the electrode substrate 311 through the transmission electrode layer 312 and the electrode protection layer 313. The transmission electrode 310 provided with the transmission electrode layer 312 is employed in place of the transmission electrode 310 for the plasma processing apparatus 300 according to the first or the second embodiment.

The apparatus according to the present embodiment is structured to have the thickness of the transmission electrode layer 312 positionally changed. For example, referring to FIG. 21, the transmission electrode layer 312 has the thickness changed depending on the position in the radial direction of the processing chamber (direction orthogonal to the center axis of the cylindrical coil 305). Specifically, it becomes thick around the center, and thin toward the edge portion. In the example illustrated in FIG. 21, the thickness of the transmission electrode layer 312 continuously changes. However, the thickness of the transmission electrode layer 312 may be changed stepwise. The structure according to the present embodiment is capable of changing the power transmission factor R_{W}_{_{—}}ₜₑ of the discharging electromagnetic wave 302 in the transmission electrode 312 depending on the position in the radial direction of the processing chamber. This makes it possible to make the distribution of power supplied to the discharging region of the discharging electromagnetic wave 302 uniform. Furthermore, the distribution of power supplied to the discharging region of the discharging electromagnetic wave 302 may be controlled. The power supplied to the discharging region of the discharging electromagnetic wave 302 is likely to be increased around the center of the processing chamber. In this case, the thickness of the transmission electrode layer 312 at the portion around the center is made relatively large such that the power transmission factor R_{W}_{_{—}}ₜₑ of the discharging electromagnetic wave 302 around the center to be lowered compared with the one at the area around the edge, thus realizing the uniform power supply to the discharging region. Alternatively the standing wave (stationary wave) of the discharging electromagnetic wave 302 occurs to have the incident intensity of the discharging electromagnetic wave 302 to the transmission electrode 310 periodically changed (distributed) in the radial direction or circumferential direction of the transmission electrode 310. In such a case, the thickness of the transmission electrode layer 312 is changed radially or circumferentially to realize the uniform power supply to the discharging region. Generally, the thickness of the transmission electrode layer 312 is made relatively large around the region where the incident intensity of the discharging electromagnetic wave 302 to the transmission electrode 310 is enhanced so as to realize the uniform power supply to the discharging region. The aforementioned technique is applicable when the change in the incident intensity of the discharging electromagnetic wave 302 to the transmission electrode 310 is not necessarily “periodical”.

### Eighth Embodiment

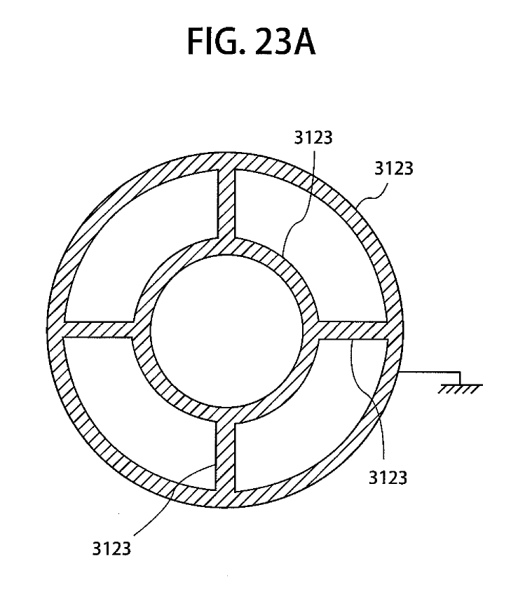

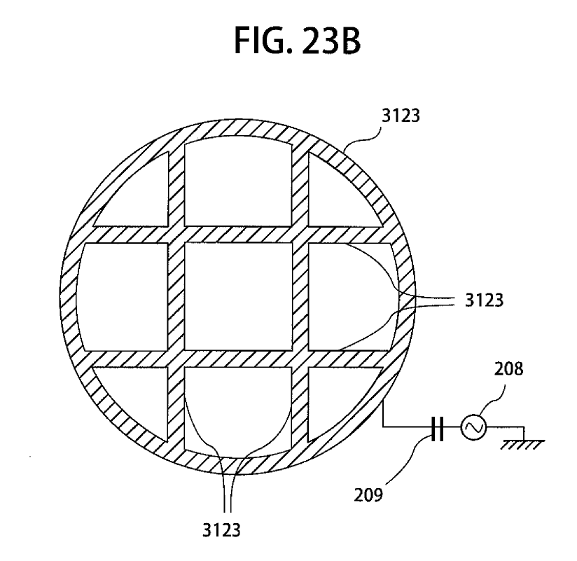

A plasma processing apparatus according to an eighth embodiment of the present invention will be described referring to FIGS. 22, 23A and 23B. FIG. 22 is a partially sectional view of the transmission electrode 310. The discharging electromagnetic wave 302 (or a part thereof) is supplied to the discharging region from the electrode substrate 311 through the transmission electrode layer 312 and the electrode protection layer 313.

In the apparatus according to the present invention, a bus electrode 3123 is formed of the material with electric conductivity, for example, electric semiconductor or the electric conductor, and is at least partially connected to at least a part of the transmission electrode layer 312 electrically through circuit. The bus electrode 3123 is electrically connected to the potential connected to the transmission electrode 312, the ground potential which is the same as the power source, or the RF power source voltage. Referring to FIG. 23A, the bus electrode is connected to the ground potential, and referring to FIG. 23B, the bus electrode is connected to the RF power source voltage. The transmission electrode 310 is employed in place of the transmission electrode 310 for the plasma processing apparatus 300 according to the first or the second embodiment.

The resistance of the bus electrode 3123 is designed and structured to be smaller than the resistance of the transmission electrode layer 312. The interval L₀ between the bus electrodes and the width W_{b} of the bus electrode are designed and structured to allow the discharging electromagnetic wave 302 (or part thereof) to pass through the gap between the bus electrodes. The thus provided bus electrode makes it possible to reduce the RF drop voltage ΔV_{rb}_{_{—}}ₜₑ as a whole transmission electrode without influencing the power transmission factor R_{W}_{_{—}}ₜₑ of the discharging electromagnetic wave nor the local flow of the RF current. This makes it possible to suppress heat generation by the RF current as a whole transmission electrode. The bus electrode is formed of the material with high electric conductivity, that is, electrical conductor for the purpose of realizing the aforementioned function. However, the material for forming the bus electrode does not have to be the electrical conductor. The electrical semiconductor may be used for forming the bus electrode to achieve the function in a limited manner. In consideration of the feature and the manufacturing ease, the thickness of the bus electrode in the range from 1×10⁻⁴ mm to 1 mm is appropriate, and the thickness in the range from 1×10⁻⁴ mm to 0.01 mm is more appropriate. The width W_{b} in the range from 0.01 mm to 10 mm is appropriate, and the width in the range from 0.1 mm to 1 mm is more appropriate. Those values are not necessarily limited to those described above. The structure of the bus electrode may be designed with arbitrary values in accordance with the circumstances to achieve the aforementioned functions.

FIGS. 23A and 23B are plan views of the transmission electrode 310 according to the eighth embodiment of the present invention. Each of FIGS. 23A and 23B shows the specific example of the shape of the bus electrode 3123 as shaded region. In the embodiment, the transmission electrode layer is divided into plural regions by the bus electrode 3123. FIG. 23A illustrates the structure based on the circular wiring, and FIG. 23B illustrates the structure based on the matrix-like wiring. Each of FIGS. 23A and 23B shows a mere example of the shape of the bus electrode 3123. It is clearly understood that the structure is not limited to the illustrated shape.

The transmission electrode layer 312 and the like in the third to eighth embodiments may be appropriately combined. For example, the transmission electrode 310 and the gas flow passage 315 according to the fifth embodiment may be combined with the transmission electrode cooling member 317 according to the sixth embodiment. The bus electrode according to the eighth embodiment may further be added to the aforementioned combined structure. This makes it possible to provide the plasma processing apparatus with various processing features.

What is claimed is:

1. A plasma processing apparatus including a processing chamber, a unit for introducing processing gas into the processing chamber, a unit for partially generating a discharge in at least a part of a region in the processing chamber, and a sample holding unit for holding a sample, all of which form at least a part of a component for performing a plasma processing by introducing the sample into the processing chamber, the apparatus further comprising a unit for introducing a discharging electromagnetic wave into the processing chamber as at least a part of the unit for generating the discharge,
wherein:
at least a part of the discharging electromagnetic wave is introduced into a discharging region where the discharge is generated via a transmission electrode;
a transmission electrode layer is provided as at least a part of a component of the transmission electrode;
the transmission electrode layer is formed of an electric semiconductor or an electric conductor as a material with electric conductivity; and
the sample held by the sample holding unit and the transmission electrode or the transmission electrode layer are oppositely arranged.

2. A plasma processing apparatus including a processing chamber, a unit for introducing processing gas into the processing chamber, a unit for partially generating a discharge in at least a part of a region in the processing chamber, and a sample holding unit for holding a sample, all of which form at least a part of a component for performing a plasma processing by introducing the sample into the processing chamber, the apparatus further comprising a unit for introducing a discharging electromagnetic wave into the processing chamber as at least a part of the unit for generating the discharge,
wherein:
at least a part of the discharging electromagnetic wave is introduced into a discharging region where the discharge is generated via a transmission electrode;
a transmission electrode layer is provided as at least a part of a component of the transmission electrode;
the transmission electrode layer is formed of an electric semiconductor or an electric conductor as a material with electric conductivity; and
a unit for forming a magnetic field is provided in at least a part of the discharging region.

3. A plasma processing apparatus including a processing chamber, a unit for introducing processing gas into the processing chamber, a unit for partially generating a discharge in at least a part of a region in the processing chamber, and a sample holding unit for holding a sample, all of which form at least a part of a component for performing a plasma processing by introducing the sample into the processing chamber, the apparatus further comprising a unit for introducing a discharging electromagnetic wave into the processing chamber as at least a part of the unit for generating the discharge,
wherein:
at least a part of the discharging electromagnetic wave is introduced into a discharging region where the discharge is generated via a transmission electrode;
a transmission electrode layer is provided as at least a part of a component of the transmission electrode;
the transmission electrode layer is formed of an electric semiconductor or an electric conductor as a material with electric conductivity; and
a frequency of the discharging electromagnetic wave is in a range from 0.1 GHz to 10 GHz.

4. A plasma processing apparatus including a processing chamber, a unit for introducing processing gas into the processing chamber, a unit for partially generating a discharge in at least a part of a region in the processing chamber, and a sample holding unit for holding a sample, all of which form at least a part of a component for performing a plasma processing by introducing the sample into the processing chamber, the apparatus further comprising a unit for introducing a discharging electromagnetic wave into the processing chamber as at least a part of the unit for generating the discharge,
wherein:
at least a part of the discharging electromagnetic wave is introduced into a discharging region where the discharge is generated via a transmission electrode;
a transmission electrode layer is provided as at least a part of a component of the transmission electrode;
the transmission electrode layer is formed of an electric semiconductor or an electric conductor as a material with electric conductivity; and
a resistivity of a material for forming the transmission electrode layer is equal to or smaller than 3×10⁻⁷ Ωm.

5. A plasma processing apparatus including a processing chamber, a unit for introducing processing gas into the processing chamber, a unit for partially generating a discharge in at least a part of a region in the processing chamber, and a sample holding unit for holding a sample, all of which form at least a part of a component for performing a plasma processing by introducing the sample into the processing chamber, the apparatus further comprising a unit for introducing a discharging electromagnetic wave into the processing chamber as at least a part of the unit for generating the discharge,
wherein:
at least a part of the discharging electromagnetic wave is introduced into a discharging region where the discharge is generated via a transmission electrode;
a transmission electrode layer is provided as at least a part of a component of the transmission electrode;
the transmission electrode layer is formed of an electric semiconductor or an electric conductor as a material with electric conductivity; and
when physical quantity is expressed in International System of Units (SI system of units), following formulae (A1) to (A3) are established,
ρₜₑ_{_{—}}_{RW}(R_{W}_{_{—}}ₜₑ=0.97)<ρₜₑ<ρₜₑ_{_{—}}_{Vrb}(ΔV_{rb}_{_{—}}ₜₑ=3V) (A1)
ρₜₑ_{_{—}}_{RW}=((2dₜₑ/ln(R_{W}_{_{—}}ₜₑ))²μₜₑ ω̅_{pf})/2 (A2)
ρₜₑ_{_{—}}_{Vrb}=(4dₜₑΔV_{rb}_{_{—}}ₜₑ)/(iᵢₛrₜₑ²) (A3)
where:
ρₜₑ: resistivity of transmission electrode layer,
dₜₑ: thickness of transmission electrode layer,
R_{W}_{_{—}}ₜₑ: power transmission factor of discharging electromagnetic wave in transmission electrode layer,
μₜₑ: permeability of transmission electrode layer,
ω_{pf}: angular frequency of discharging electromagnetic wave,
ΔVₜₑ_{_{—}}ₜₑ: RF drop voltage in transmission electrode layer,
iᵢₛ: incident ion current density of transmission electrode to the surface at discharging region side, and
rₜₑ: radius or equivalent radius of transmission electrode layer,
wherein following formula (B1) provides the value of rₜₑ_{_{—}}_{RW} by calculating the formula (A2) using R_{W}_{_{—}}ₜₑ=0.97, and following formula (B2) provides the value of rₜₑ_{_{—}}_{Vrb} by calculating the formula (A3) using DV_{rb}_{_{—}}ₜₑ=3V.
ρₜₑ_{_{—}}_{RW}(R_{W}_{_{—}}ₜₑ=0.97) (B1)
ρₜₑ_{_{—}}_{Vrb}(ΔV_{rb}_{_{—}}ₜₑ=3V) (B2)

6. The plasma processing apparatus according to claim 1, wherein:
a bus electrode is provided as a part of the component of the transmission electrode;
the bus electrode is formed of the electric semiconductor or the electric conductor as a material with electric conductivity; and
at least a part of the bus electrode is electrically coupled with at least a part of the transmission electrode layer via circuit.

7. The plasma processing apparatus according to claim 6, wherein the transmission electrode layer is divided into plural regions by the bus electrode.

8. The plasma processing apparatus according to claim 1, wherein:
at least a transmission electrode layer missing region is formed in at least a part of the transmission electrode layer; and
the transmission electrode layer missing region is configured in the transmission electrode layer where the material with electric conductivity for forming the transmission electrode layer is missing.

9. The plasma processing apparatus according to claim 8, wherein at least a part of the processing gas is introduced into the processing chamber through the transmission electrode layer missing region formed in the transmission electrode layer.

10. The plasma processing apparatus according to claim 1, wherein a thickness of the transmission electrode layer changes depending on a radial or circumferential position of the processing chamber.
